(19) United States
(12) Patent Application Publication
(10) Pub. No.: US 2025/0185300 A1
(43) Pub. Date: Jun. 5, 2025

(54) ELECTRONIC DEVICES EMPLOYING THIN-GATE INSULATOR TRANSISTORS COUPLED TO VARACTORS TO REDUCE GATE-TO-SOURCE/DRAIN VOLTAGE TO AVOID VOLTAGE BREAKDOWN, AND RELATED FABRICATION METHODS

(71) Applicant: QUALCOMM Incorporated, San Diego, CA (US)

(72) Inventors: Qingqing Liang, San Diego, CA (US); Yan Sun, San Diego, CA (US); Lixin Ge, San Diego, CA (US); Jun Yuan, San Diego, CA (US); Giridhar Nallapati, San Diego, CA (US); Periannan Chidambaram, San Diego, CA (US)

(21) Appl. No.: 18/529,087

(22) Filed: Dec. 5, 2023

(51) Int. Cl. H01L 29/423; H01L 21/8238; H01L 27/02; H01L 27/07; H01L 29/06; H01L 29/66; H01L 29/775; H01L 29/78; H01L 29/786

(52) U.S. Cl. CPC H10D 30/6735; H10D 1/045; H10D 30/014; H10D 30/024; H10D 30/43; H10D 30/62; H10D 30/6757; H10D 62/121; H10D 64/017; H10D 84/0167; H10D 84/0193; H10D 84/038; H10D 84/811; H10D 89/601

(57) ABSTRACT

Electronic devices employing thin-gate insulator transistors coupled to varactors to reduce gate-to-source/drain voltage to avoid voltage breakdown, and related fabrication methods. The electronic device includes thin-gate insulator transistors coupled in series to provide a single output node, and with their gates controlled by a single, input node to provide an effective three (3) terminal, single transistor device. The electronic device includes varactors each coupled in series between a respective gate of a thin-gate insulator transistor and the input node to support a single input signal for the electronic device. Each series coupled varactor and thin-gate insulator transistor are coupled to the input node in parallel to each other. Each varactor creates a voltage division between the input signal voltage and its series connected gate of a respective thin-gate insulator transistor to prevent the respective gate-to-source/drain voltage of the thin-gate insulator transistor from exceeding its breakdown voltage.

### BACKGROUND

### I. Field of the Disclosure

The field of the disclosure relates to integrated circuits (ICs) and related semiconductor dies (“dies”) employing an interconnect structure fabricated through a back-end-of-line (BEOL) process for interconnecting semiconductor devices in the die.

### II. BACKGROUND

Transistors are essential components in modern electronic devices. Large numbers of transistors are employed in integrated circuits (ICs) in many modern electronic devices. For example, components such as central processing units (CPUs), digital signal processors (DSPs), and memory systems each employ a large quantity of transistors for logic circuits and memory devices. One type of transistor is a field-effect transistor (FET). A FET uses an electric field to control the flow of current between a source and a drain. The flow of current is controlled by application of a voltage to a gate of the FET, which in turn alters the conductivity between the source and the drain. Different types of FETs include planar FETs, Fin FETs (FinFETs), and gate-all-around (GAA) FETs. FinFETs and GAA FETs have an advantage of better channel control with their gates partially or fully disposed around the semiconductor channel. These FETs can be used to form complementary metal oxide semiconductor (CMOS) logic circuits that include one or more P-type semiconductor (P-type) FETs and one or more N-type semiconductor (N-type) FETs.

FETs that are used to provide input/output (I/O) interface circuits and electro-static discharge (ESD) protection circuits are typically required to be able to support a gate-to-source voltage (V_{GS}) and drain-to-source voltage (V_{DS}) of at least 1.2 Volts (V), and sometimes higher voltages of up to 1.5 V or 1.8 V. However, in CMOS fabrication technologies, such as for GAA FETs, the V_{GS} and V_{DS} of the GAA FET is restricted to a lower voltage (e.g., <=0.9 V) due to the gate oxide thickness limitations. Gate oxide is provided in a FET to insulate the semiconductor channel from the gate. As an example, in a GAA FET, gate oxide layers are disposed adjacent to each of the top and bottom of each stacked nano channel structure (e.g., nanowires or nanosheets), as opposed to FinFETs where a single gate oxide layer is disposed around a fin semiconductor channel structure(s). Thus, with a gate oxide layer disposed adjacent to both the top and bottom of each nano channel structure, the individual thicknesses of the gate oxide layers effectively add together to affect the overall height of the GAA FET. Thus, it may be desired or required to provide for the gate oxide layers disposed around the nano channel structures to be thinner to mitigate an increased height of the GAA FET. Also, a thinner gate oxide can reduce short-channel effects (SCEs) in a FET by providing improved gate control over shorter channel lengths. However, when the gate oxide is too thin in a FET, it can lead to issues such as gate leakage and voltage breakdown, which can result in reliability problems and device failure.

A stacked FET device can be provided that includes multiple thin gate oxide FETs coupled together to provide multiple gate inputs with fixed voltage inputs to provide voltage offsets for signal voltage inputs that have limited voltage range to prevent voltage breakdown, while still providing a full voltage range output. However, voltage level shifters may be required to create different voltage domains to drive the multiple inputs over their respective limited voltage ranges to avoid voltage breakdown, but at a cost of increased area and power consumption. Also, the voltage signals on the multiple inputs have to be synchronized for the stacked FET device to generate an intended output signal.

### SUMMARY OF THE DISCLOSURE

Exemplary aspects disclosed in the detailed description include electronic devices employing thin-gate insulator transistors coupled to varactors to reduce gate-to-source/drain voltage to avoid voltage breakdown. Related fabrications methods are also disclosed. The electronic device includes two (2) or more thin-gate insulator (e.g., thin-gate oxide) transistors in series to each other from source to drain to provide a single output node, and with their gates controlled by a single input node to provide an effective three (3) terminal, single transistor device. In this regard, the electronic device is configured to be powered by a supply voltage coupled across the multiple transistors so that the gate-to-source voltage (V_{GS}) and drain-to-source voltage (VGD) applied to each individual transistor is reduced. In this manner, as an example, the transistors in the electronic device may be provided as thin-gate insulator devices that have a breakdown voltage (e.g., 0.9 Volts (V)) less than the supply voltage (e.g., >0.9 V) to obtain thin-gate insulator benefits of reduced short-channel effects (SCEs) and/or to reduce the overall height of the transistors to conserve die area. However, this would require the voltage range of the input signal to be limited to the breakdown voltage of the transistors, which would then limit the voltage range of the output signal of the electronic device in an undesired manner. Or alternatively, voltage level shifting would be required to provide synchronized and limited voltage range gate input signals with additional series coupled transistors having fixed gate voltages to provide offset voltages to limit voltage differential across the transistors, thereby increasing area and cost in an undesired manner. In this regard, in exemplary aspects disclosed herein, the electronic device includes varactors each coupled in series between a respective gate of a thin-gate insulator transistor and the input node to support a single input signal for the electronic device. Each series coupled varactor and thin-gate insulator transistor are coupled to the input node in parallel to each other. Each varactor creates a voltage division between the input signal voltage and its series connected gate of a respective thin-gate insulator transistor to prevent the respective gate-to-source/drain voltage of the thin-gate insulator transistor from exceeding its breakdown voltage.

This allows the electronic device to be powered by a higher supply voltage than the breakdown voltage of the thin-gate insulator transistors and varactors, while eliminating the need for voltage shifting to provide multiple, synchronized input signals and added transistors with fixed gate voltages to provide offset voltages to avoid exceeding the breakdown voltages of the thin-gate insulator transistors. The electronic devices disclosed herein can be provided as a single input device, without the need for separated gate signal inputs with limited voltage range and requiring voltage level shifting, and additional transistors to provide fixed offset voltages to limit the gate-to-source/drain voltages of the thin-gate insulator transistors. As an example, the electronic devices that include varactors coupled in series to the respective gates of a thin-gate insulator transistor can be employed in applications that have larger supply voltages, such as input/output (I/O) circuits or electro-static discharge (ESD) circuits, for example, but using transistors that have a voltage breakdown less than the supply voltages. This allows the transistors employed in the electronic device to be thin-gate insulator transistors that have a reduced breakdown voltage, but provide the benefits of reduced SCEs and/or volume. Also, the inclusion of the series coupled varactors in the electronic device provide signal isolation between the input node and the gates of the thin-gate insulator transistor. Thus, the gates of the thin-gate insulator transistor are floating when no input signal is applied to the input node to reduce or avoid current leakage in the electronic device.

In other exemplary aspects, the varactors of the electronic device may also have thin-gate insulators. The thickness and other properties of the gate insulators of the varactors and the respective coupled thin-gate insulator transistors can be fabricated to achieve the desired impedance and thus voltage divider properties. For example, if the properties of the gate insulator of the varactors and its respective coupled thin-gate insulator transistors are the same, the input voltage will be divided evenly between varactor and its series coupled thin-gate insulator transistor. The impedance matching or mismatch between the different series coupled varactor and thin-gate insulator transistor circuits can be the same or different according to the desired design.

In one exemplary aspect, an electronic device is disclosed. The electronic device includes a first field-effect transistor (FET) comprising a first gate, a first terminal, and a second terminal. The electronic device also includes a second FET comprising a second gate, a third terminal, and a fourth terminal, the third terminal coupled in series to the second terminal. The electronic device also includes a first varactor circuit comprising a first anode and a first cathode, the first cathode coupled to the first gate. The electronic device also includes a second varactor circuit comprising a second anode and a second cathode, the second cathode coupled to the second gate. The electronic device also includes an input node comprising the first anode coupled to the second anode. The electronic device also includes an output node coupled to at least one of the second terminal and the third terminal.

In another exemplary aspect, an electronic device is disclosed. The electronic device includes a first circuit. The first circuit includes a first diffusion region in a substrate having a first polarity. The first circuit also includes a first varactor circuit comprising a first anode and a first cathode formed in the first diffusion region. The first circuit also includes a second varactor circuit comprising a second anode and a second cathode formed in the first diffusion region. The first circuit also includes a second diffusion region in the substrate having a second polarity opposite from the first polarity. The first circuit also includes a first FET comprising a first gate, a first terminal, and a second terminal in the second diffusion region. The first circuit also includes a second FET comprising a second gate, a third terminal, and a fourth terminal in the second diffusion region, the third terminal coupled in series to the second terminal. The first circuit also includes a first gate structure extending in the first diffusion region and the second diffusion region and comprising the first gate of the first FET in the second diffusion region, the first gate structure coupled to the first cathode to couple the first cathode to the first gate. The first circuit also includes a second gate structure extending in the first diffusion region and the second diffusion region and comprising the second gate of the second FET in the second diffusion region, the second gate structure coupled to the second cathode to couple the second cathode to the second gate. The electronic device also includes an input node coupled to the first anode and the second anode. The electronic device also includes an output node coupled to at least one of the second terminal and the third terminal.

In another exemplary aspect, a method of fabricating an electronic device is disclosed. The method includes forming a first diffusion region in a substrate having a first polarity. The method also includes forming a first varactor circuit comprising a first anode and a first cathode, and a second varactor circuit comprising a second anode and a second cathode in the first diffusion region. The method also includes forming a second diffusion region in the substrate having a second polarity opposite from the first polarity. The method also includes forming a first field-effect transistor (FET) comprising a first gate, a first terminal, and a second terminal, and a second FET comprising a second gate, a third terminal, and a fourth terminal in the second diffusion region, the third terminal coupled in series to the second terminal. The method also includes forming a first gate structure extending in the first diffusion region and the second diffusion region and comprising the first gate of the first FET in the second diffusion region, the first gate structure coupled to the first cathode to couple the first cathode to the first gate. The method also includes forming a second gate structure extending in the first diffusion region and the second diffusion region and comprising the second gate of the second FET in the second diffusion region, the second gate structure coupled to the second cathode to couple the second cathode to the second gate.

### BRIEF DESCRIPTION OF THE FIGURES

FIG. 1 is a diagram of an electronic device that includes multiple, stacked field-effect transistors (FETs) coupled to each other to provide a single full voltage range output and having multiple limited voltage range inputs to avoid voltage breakdown of the individual FETs;

FIGS. 2A-1 and 2A-2 are circuit diagrams of an exemplary three (3) terminal electronic device that includes two (2) varactors each coupled in series to a respective gate of two (2) thin-gate insulator transistors, to provide a voltage divider of an input signal between each varactor and its respective series coupled gate of a thin-gate insulator transistor to support a higher supply voltage than the breakdown voltages of the thin-gate insulator transistors;

FIG. 2B is a circuit layout diagram of the electronic device in FIGS. 2A-1 and 2A-2 that includes two (2) P-type semiconductor (P)+/P-well varactors each coupled in series to two (2) thin-gate insulator N-type semiconductor (N) field-effect transistors (NFETs);

FIG. 2C is a circuit layout diagram of the electronic device in FIGS. 2A-1 and 2A-2 that includes two (2) N+/N-well varactors each coupled in series to two (2) thin-gate insulator PFETs;

FIG. 3A is a circuit diagram of an exemplary three (3) terminal electronic device that includes three (3) varactors each coupled in series to a respective gate of three (3) thin-gate insulator transistors, to provide a voltage divider of an input signal between each varactor and its respective series coupled gate of a thin-gate insulator transistor to support a higher supply voltage than the breakdown voltages of the thin-gate insulator transistors;

FIG. 3B is a circuit layout diagram of the electronic device in FIG. 3A that includes three (3) P+/P-well varactors each coupled in series to three (3) thin-gate insulator NFETs;

FIG. 3C is a circuit layout diagram of the electronic device in FIG. 3A that includes three (3) N+/N-well varactors each coupled in series to three (3) thin-gate insulator PFETs;

FIG. 4A is a circuit diagram of an exemplary three (3) terminal electronic device that includes three (3) varactor circuits each comprising two (2) series coupled varactors each coupled in series between an input node and a respective gate of a thin-gate insulator transistor, to provide a voltage divider of an input signal between each varactor circuit and its respective series coupled gate of a thin-gate insulator transistor to support a higher supply voltage than the breakdown voltages of the thin-gate insulator transistors;

FIG. 4B is a circuit layout diagram of the electronic device in FIG. 4A that includes three (3) varactor circuits each comprising two (2) series coupled P+/P-well varactors each coupled in series to three (3) thin-gate insulator NFETs;

FIG. 4C is a circuit layout diagram of the electronic device in FIG. 4A that includes three (3) varactor circuits each comprising two (2) series coupled N+/N-well varactors each coupled in series to three (3) thin-gate insulator PFETs;

FIG. 5 is a flowchart illustrating an exemplary method of fabricating a three (3) terminal electronic device that includes a plurality of varactors each coupled in series to a respective gate of a thin-gate insulator transistor, to provide a voltage divider of an input signal between each varactor and its respective series coupled gate of a thin-gate insulator transistor to support a higher supply voltage than the breakdown voltages of the thin-gate insulator transistors;

FIG. 6 is a block diagram of an exemplary wireless communications device that includes radio-frequency (RF) components that can include a three (3) terminal electronic device that includes a plurality of varactors each coupled in series to a respective gate of a thin-gate insulator transistor, to provide a voltage divider of an input signal between each varactor and its respective series coupled gate of a thin-gate insulator transistor to support a higher supply voltage than the breakdown voltages of the thin-gate insulator transistors, including, but not limited, to the electronic devices in FIGS. 2A-1-4C, and according to any fabrication processes, including, but not limited to, the exemplary fabrication process in FIG. 5; and

FIG. 7 is a block diagram of an exemplary processor-based system that can include a three (3) terminal electronic device that includes a plurality of varactors each coupled in series to a respective gate of a thin-gate insulator transistor, to provide a voltage divider of an input signal between each varactor and its respective series coupled gate of a thin-gate insulator transistor to support a higher supply voltage than the breakdown voltages of the thin-gate insulator transistors, including, but not limited, to the electronic devices in FIGS. 2A-1-4C, and according to any fabrication processes, including, but not limited to, the exemplary fabrication process in FIG. 5.

### DETAILED DESCRIPTION

With reference now to the drawing figures, several exemplary aspects of the present disclosure are described. The word “exemplary” is used herein to mean “serving as an example, instance, or illustration.” Any aspect described herein as “exemplary” is not necessarily to be construed as preferred or advantageous over other aspects.

Exemplary aspects disclosed in the detailed description include electronic devices employing thin-gate insulator transistors coupled to varactors to reduce gate to source/drain voltage to avoid voltage breakdown. Related fabrications methods are also disclosed. The electronic device includes two (2) or more thin-gate insulator (e.g., thin-gate oxide) transistors in series to each other from source to drain to provide a single output node, and with their gates controlled by a single input node to provide an effective three (3) terminal, single transistor device. In this regard, the electronic device is configured to be powered by a supply voltage coupled across the multiple transistors so that the gate-to-source voltage (V_{GS}) and drain-to-source voltage (VGD) applied to each individual transistor is reduced. In this manner, as an example, the transistors in the electronic device may be provided as thin-gate insulator devices that have a breakdown voltage (e.g., 0.9 Volts (V)) less than the supply voltage (e.g., >0.9 V) to obtain thin-gate insulator benefits of reduce short-channel effects (SCEs) and/or to reduce the overall height of the transistors to conserve die area. However, this would require voltage range of the input signal to be limited to the breakdown voltage of the transistors, which would then limit the voltage range of the output signal of the electronic device in an undesired manner. Or alternatively, voltage level shifting would be required to provide synchronized and limited voltage range, gate input signals with additional series coupled transistors having fixed gate voltages to provide offset voltages to limit voltage differential across the transistors, thereby increasing area and cost in an undesired manner. In this regard, in exemplary aspects disclosed herein, the electronic device includes varactors each coupled in series between a respective gate of a thin-gate insulator transistor and the input node to support a single input signal for the electronic device. Each series coupled varactor and thin-gate insulator transistor are coupled to the input node in parallel to each other. Each varactor creates a voltage division between the input signal voltage and its series connected gate of a respective thin-gate insulator transistor to prevent the respective gate to source/drain voltage of the thin-gate insulator transistor from exceeding its breakdown voltage.

This allows the electronic device to be powered by a higher supply voltage than the breakdown voltage of the thin-gate insulator transistors and varactors, while the need for voltage shifting to provide multiple, synchronized input signals and added transistors with fixed gate voltages to provide offset voltages to avoid exceeding the breakdown voltages of the thin-gate insulator transistors. The electronic devices disclosed herein can be provided as a single input device, without the need for separated gate signal inputs with limited voltage range and requiring voltage level shifting, and additional transistors to provide fixed offset voltages to limit the gate to source/drain voltages of the thin-gate insulator transistors. As an example, the electronic devices that include varactors coupled in series to the respective gates of a thin-gate insulator transistor can be employed in applications that have larger supply voltages, such as input/output (I/O) circuits or electro-static discharge (ESD) circuits, for example, but using transistors that have a voltage breakdown less than the supply voltages. This allows the transistors employed in the electronic device to be thin-gate insulator transistors that have a reduced breakdown voltage, but provide benefits of reduced SCEs and/or volume. Also, the inclusion of the series coupled varactors in the electronic device provide signal isolation between the input node and the gates of the thin-gate insulator transistor. Thus, the gates of the thin-gate insulator transistor are floating when no input signal is applied to the input node to reduce or avoid current leakage in the electronic device.

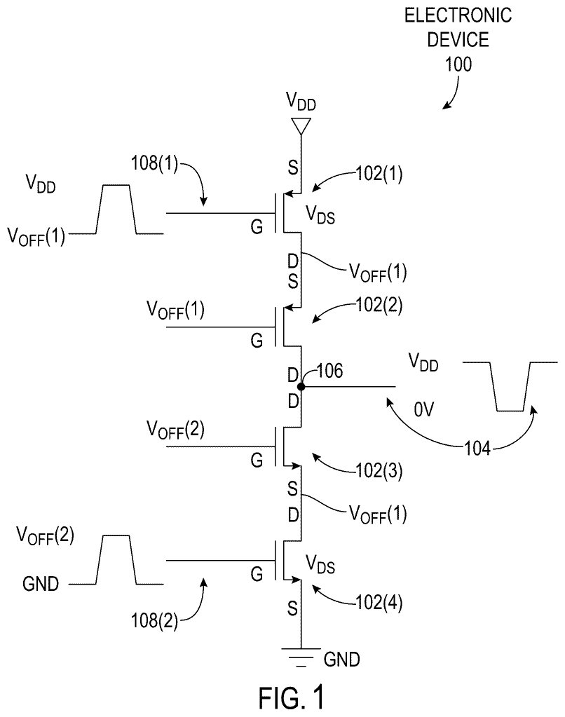

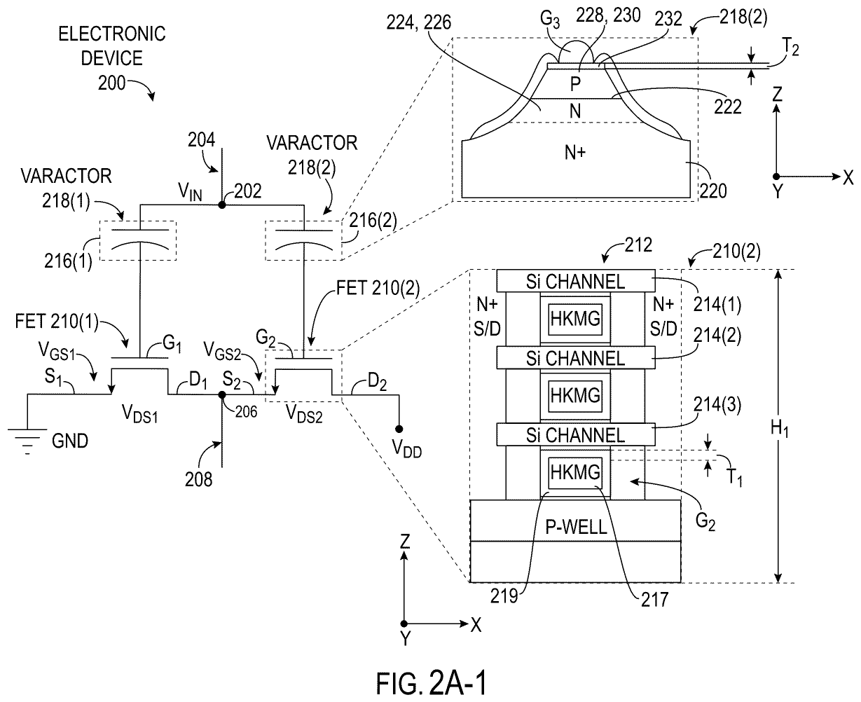

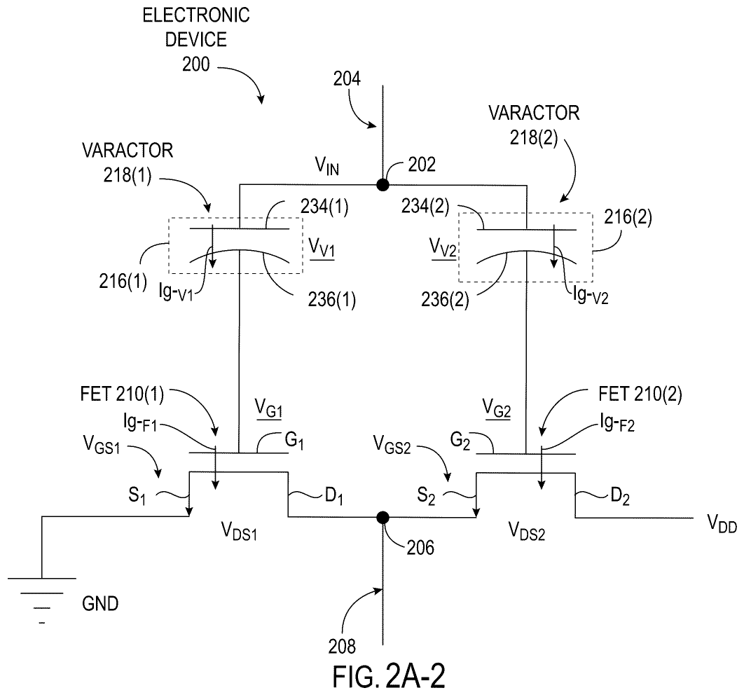

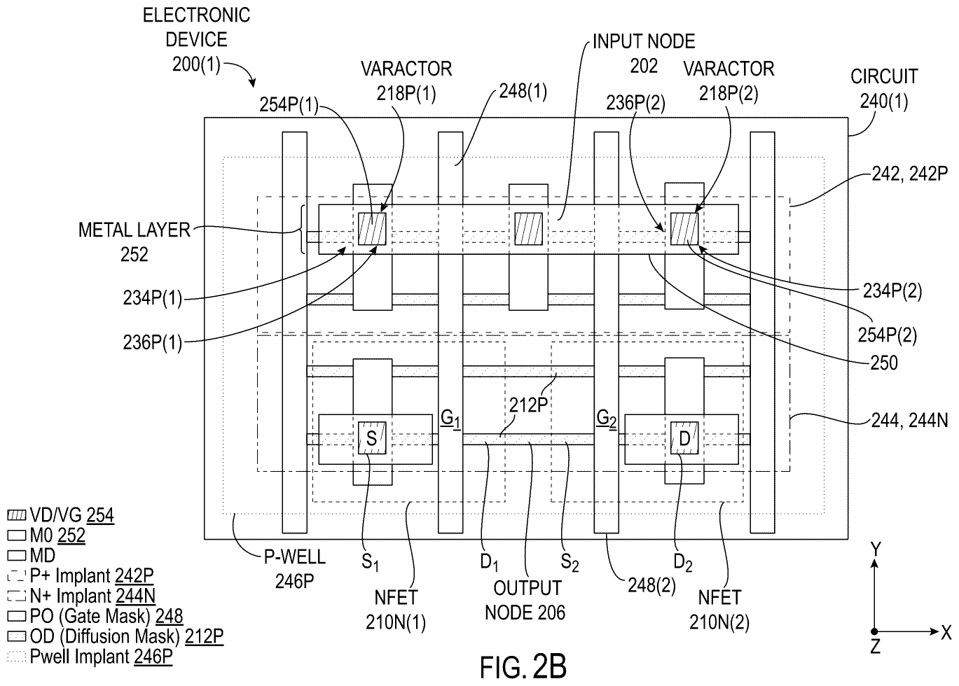

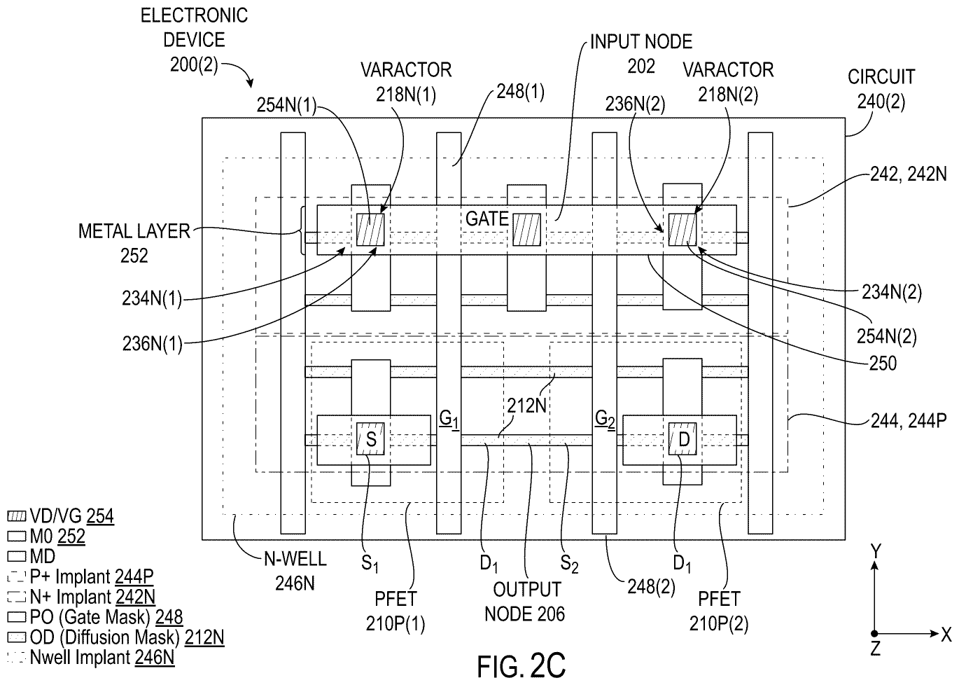

Before discussing examples of electronic devices employing thin-gate insulator transistors coupled to varactors to reduce gate-to-source/drain voltage to avoid voltage breakdown starting at FIG. 2A-1, an electronic device that includes multiple, stacked FETs having multiple limited voltage range inputs to avoid voltage breakdown of the individual FETs is first discussed with regard to FIG. 1.

In this regard, FIG. 1 is a diagram of an electronic device 100 that includes multiple, stacked FETs 102(1)-102(4) coupled to each other in series to provide a three (3) terminal device that operates like a FET. The electronic device 100 is configured to generate an output signal 104 on an output node 106 based on the full voltage range of a supply voltage V_{DD} (e.g., 1.2 Volts (V)) in response to input signals 108(1), 108(2). However, in this electronic device 100, the FETs 102(1)-102(4) have a breakdown voltage (e.g., 0.9 V) that is less than the supply voltage V_{DD}. This may be due to the desire to reduce the thickness of the gate insulator (e.g., gate oxide) in the FETs 102(1)-102(4) to improve performance and conserve area (e.g., height) of the FETs 102(1)-102(4). For example, it may be desired to employ the electronic device 100 in applications such as input/output (I/O) circuits and electro-static discharge (ESD) circuits, where supply voltage is higher. Thus, in this example, the supply voltage V_{DD} cannot be applied across the gate G and source S of the FETs 102(1), 102(4), or drain D and source S of the FETs 102(1), 102(4) without risking voltage breakdown and damage to the FETs 102(1), 102(4). In this example, to avoid voltage breakdown of the FETs 102(1), 102(4), additional FETs 102(2), 103(3) are provided and coupled in series with the FETs 102(1), 102(4) in the electronic device 100. The FETs 102(2), 102(3) are configured to receive a fixed voltage (e.g., 0.5 V and 0.7 V) on their respective gates G to apply respective offset voltages VOFF(1), VOFF(2) of the fixed voltages as a gate-to-source voltage (V_{GS}) of the FETs 102(2), 102(3). This in turn reduces the drain-to-source voltages V_{DS} of the FETs 102(1), 102(4) to prevent them from having a voltage breakdown.

However, to provide for the proper operation of the FETs 102(1), 102(4) to pass the input signals 108(1), 108(2) with the new voltage operating range of the FETs 102(1), 102(4) based on the offset voltages VOFF(1), VOFF(2) applied to their respective drains D, the FETSs 102(1), 102(4) must also be provided the inputs signal 108(1), 108(2) that are voltage range limited to their drain-to-source voltages V_{DS} based on the offset voltages VOFF(1), VOFF(2) applied to the gates G of the FETs 102(2), 102(3). Thus, voltage level shifters (not shown) may be required to voltage level shift an original input signal into the separate input signals 108(1), 108(2) to be coupled to the respective gates G of the FETs 102(1), 102(4) to generate the output signal 104. Also, the input signals 108(1), 108(2) need to be synchronized for the output signal 104 to be undistorted based on an original input signal that was then voltage level shifted to the input signals 108(1), 108(2). Thus, as shown in FIG. 1, the electronic device 100 is capable of generating the output signal 104 of the voltage range of the supply voltage V_{DD} (e.g., 1.2V) based on the input signals 108(1), 108(2) with FETs 102(1)-102(4) that have a breakdown voltage less than the supply voltage V_{DD}. However, this comes at the additional cost and area of the added FETs 102(2), 102(3) as well as the need to provide synchronized, voltage level shifted inputs signals 108(1), 108(2), which may be undesired.

In this regard, to avoid the need to provide additional FETs to apply offset voltages and/or to provide synchronized, voltage level shifted inputs signals to avoid voltage breakdown, an exemplary electronic device 200 is provided in FIGS. 2A-1 and 2A-2. FIGS. 2A-1 and 2A-2 are circuit diagrams of the three (3) terminal electronic device 200 that includes a single input node 202 configured to receive an input signal 204, and an output node 206. The electronic device 200 acts like a FET device in that an output signal 208 is generated on the output node 206 based on the input signal 204 having a voltage level such that the voltage differential between respective first and second gates G₁, G₂ and first and second sources S₁, S₂ of respective first and second FETs 210(1), 210(2) (i.e., the gate-to-source voltages V_{GS1}, V_{GS2}) exceed threshold voltages of the first and second FETs 210(1), 210(2). If the gate-to-source voltages V_{GS1}, V_{GS2} of the respective first and second FETs 210(1), 210(2) exceed their threshold voltages, the first and second FETs 210(1), 210(2) will be activated (i.e., their channel activated) such that electronic device 200 will generate the output signal 208 on the output node 206 that is based on a supply voltage V_{DD} applied to the electronic device 200 to power to the electronic device 200.

In this example, it is desired to provide the first and second FETs 210(1), 210(2) as having thin-gate insulators that insulate their respective gates G₁, G₂ from their semiconductor channel to obtain thin-gate insulator benefits of reduced short-channel effects (SCEs) and/or to reduce the overall height of the FETs 210(1), 210(2) to conserve die area. This is also shown in FIG. 2A-1 in the exemplary side view of the second FET 210(2), which is a gate-all-around (GAA) FET in this example. The FETs 210(1), 210(2) could also be other types of FETs, including planar FETs and FinFETs as examples. The side view of the second FET 210(2) can also be applicable to the first FET 210(1). As shown, the second FET 210(2) includes a semiconductor channel 212 that is formed from a plurality of silicon nanosheets 214(1)-214(3) that are surrounded by the gate G₂. The gate G₂ is comprised of a gate material 217 (e.g., a metal material or poly material) insulated by a gate insulator 219 that is a dielectric material and can be a high-K dielectric material (e.g., a gate oxide) to insulate the gate material 217 from the nanosheets 214(1)-214(3). The gate insulator 219 has a defined thickness T₁ in the direction of (X- and Y-axis directions) and between the gate material 217 and a respective nanosheet 214(1)-214(3) that is desired to be minimized to improve SCEs and to reduce the overall height H₁ of the FET 210(2) to conserve die area. For example, the thickness T₁ of the gate insulator 219 may be 0.5 nanometers (nm) to 2.0 nm. However, a thin gate insulator 219 may cause the FET 210(2) to have a lower breakdown voltage (e.g., 0.9 Volts (V)) less than the supply voltage V_{DD}. This would normally then require the voltage range of the input signal 204 to be limited to the breakdown voltage of the first and second FETs 210(1), 210(2), which would then limit the voltage range of the output signal 208 of the electronic device 200 in an undesired manner. It is desired that the input signal 204 be able to be in the voltage domain and have a voltage range of the supply voltage V_{DD} powering the electronic device 200. Alternatively, additional FETs are needed to provide offset voltages to the first and second FETs 210(1), 210(2) and synchronized, voltage level shifting of the input signal 204 would be required like in the electronic device 100 in FIG. 1 for example.

To avoid the need for additional FETs to provide offset voltages and synchronized voltage level shifted input signals, the electronic device 200 includes first and second varactor circuits 216(1), 216(2), which in this example are respective first and second varactors 218(1), 218(2). As discussed in more detail below, the first and second varactors 218(1), 218(2) are each coupled in series between a respective gate G₁, G₂ of the first and second FETs 210(1), 210(2) and the input node 202 to support a single input signal 204 for the electronic device 200. Each respective varactor 218(1), 218(2) that is series coupled to a respective FET 210(1), 210(2) is coupled to the input node 202 in parallel to each other. The first and second varactors 218(1), 218(2) create a voltage division of the input voltage VIN of the input signal 204 between the respective first and second varactors 218(1), 218(2) and its respective series connected gate G₁, G₂ of the first and second FETs 210(1), 210(2). This reduces respective gate-to-source voltages V_{GS1}, V_{GS2} of the first and second FETs 210(1), 210(2) to prevent the input voltage VIN of the input signal 204 in the voltage domain of the supply voltage V_{DD} from causing the gate-to-source voltages V_{GS1}, V_{GS2} and the drain-to-source voltages V_{DS1}, V_{DS2} of the first and second FETs 210(1), 210(2) to exceed their respective breakdown voltages. An example side view of the second varactor 218(2), which is also applicable to the first varactor 218(1), is shown in FIG. 2A-1. As shown therein, in this example, the second varactor 218(2) includes an N-type semiconductor (N)+ implant 220 below a P-N junction 222 formed by an N-type semiconductor material 224 forming a cathode 226 and a P semiconductor material 228 forming an anode 230. The second varactor 218(2) includes a gate G₃ that is insulated from the anode 230 by a gate insulator 232 that is a dielectric material (e.g., a gate oxide). The gate insulator 232 has a defined thickness T₂ in the direction of (X- and Y-axis directions) and between the gate G₃ and the anode 230. For example, the thickness T₂ of the gate insulator 232 may be 0.5 nm to 2.0 nm.

Providing the varactors 218(1), 218(2) series connected between the input node 202 and the respective first and second FETs 210(1), 210(2) allows the electronic device 200 to be powered by a higher supply voltage V_{DD} than the breakdown voltage of the first and second FETs 210(1), 210(2). The need to provide voltage shifting to provide multiple, synchronized input signals and added FETs to provide fixed offset voltages to avoid exceeding the breakdown voltages of the first and second FETs 210(1), 210(2) can be avoided. As an example, the electronic device 200 can be employed in applications that have larger supply voltages, such as I/O circuits or ESD circuits, for example, but using the FETs 210(1), 210(2) that have a voltage breakdown less than the supply voltage. This allows the FETs 210(1), 210(2) employed in the electronic device 200 to be thin-gate insulator FETs that have a reduced breakdown voltage, but provide the benefits of reduced SCEs and/or area. Also, the inclusion of the series coupled varactors 218(1), 218(2) in the electronic device 200 provides signal isolation between the input node 202 and the gates G₁, G₂ of the first and second FETs 210(1), 210(2). Thus, the gates G₁, G₂ of the first and second FETs 210(1), 210(2) are floating when no input signal 204 is applied to the input node 202 to reduce or avoid current leakage in the electronic device 200.

More exemplary detail of the electronic device 200 in FIG. 2A-1 will now be discussed with reference to FIG. 2A-2. In this regard, the electronic device 200 includes the first and second FETs 210(1), 210(2) that have the respective first and second gates G₁, G₂. The first FET 210(1) has first and second terminals S₁, D₁, and the second FET 210(2) has third and fourth terminals S₂, D₂. In this example, the first and third terminals S₁, S₂ are first and second sources S₁, S₂, and the second and fourth terminals D₁, D₂ are first and second drains D₁, D₂, but the terminals could be source/drain or drain/source interchangeably. The first and second FETs 210(1), 210(2) have respective first and second breakdown voltages for their gate-to-source voltages V_{GS1}, V_{GS2} that are dictated by the thickness of the gate insulators between their respective gates G₁, G₂ and their channels (see, e.g., channel 212 in FIG. 2A-1). The first and second FETs 210(1), 210(2) also have respective first and second breakdown voltages for their drain-to-source voltages V_{DS1}, V_{DS2} that are dictated by the thickness of the gate insulators between their respective gates G₁, G₂ and their channels (see, e.g., channel 212 in FIG. 2A-1).

With continuing reference to FIG. 2A-2, the first and second FETs 210(1), 210(2) are series connected (also referred to as “stacked FETs”) in that the first drain D₁ of the first FET 210(1) is coupled to the second source S₂ of the second FET 210(2). The output node 206 is formed as a node coupled to the first drain D₁ of the first FET 210(1) and the second source S₂ of the second FET 210(2). The electronic device 200 is powered by a supply voltage V_{DD} that is connected to the second drain D₂ of the second FET 210(2), with the first source S₁ of the first FET 210(1) coupled to ground GND, which is 0 V with respect to the supply voltage V_{DD}. Thus, the supply voltage V_{DD} is applied across both the first and second FETs 210(1), 210(2) coupled in series together. The electronic device 200 is configured to generate the output signal 208 on the output node 206 in the voltage domain of the supply voltage V_{DD} based on the voltage of the input signal 204 applied to the input node 202 as discussed below.

With continuing reference to FIG. 2A-2, the electronic device 200 also includes the first and second varactor circuits 216(1), 216(2), which in this example are the respective first and second varactors 218(1), 218(2). The first varactor 218(1) includes a first anode 234(1) coupled to the input node 202, and a first cathode 236(1) coupled to the first gate G₁ of the first FET 210(1). The second varactor 218(2) includes a second anode 234(2) coupled to the input node 202, and a second cathode 236(2) coupled to the second gate G₂ of the second FET 210(2). Thus, the input node 202 in this example is coupled in parallel to the first and second anodes 234(1), 234(2) of the respective first and second varactors 218(1), 218(2). Thus, with the presence of the first and second varactors 218(1), 218(2) coupled in series to and between the input node 202 and the respective first and second FETs 210(1), 210(2), a voltage division of the input voltage VINoccurs. The input voltage VINis divided between the first varactor 218(1) and its series coupled first FET 210(1) based on the relative impedances of the first varactor 218(1) and its series coupled first FET 210(1). The input voltage VIN is also divided between the second varactor 218(1) and its series coupled second FET 210(2) based on the relative impedances of the second varactor 218(2) and its series coupled second FET 210(2). In this manner, an input signal 204 having the input voltage VIN in the voltage domain and voltage range of the supply voltage V_{DD} is not directly applied to the first and second gates G₁, G₂ of the respective first and second FETs 210(1), 210(2). A reduced gate voltage V_{G1}, V_{G2} of the input voltage V_{IN} is applied to the first and second gates G₁, G₂ of the respective first and second FETs 210(1), 210(2).

In this example electronic device 200 in FIG. 2A-2, for an alternating current (AC) input signal 204, the gate voltage V_{G1}=C varactor 218(1)/(C varactor 218(1)+C FET 210(1))*input voltage V_{IN}, and the gate voltage V_{G2}=C varactor 218(2)/(C varactor 218(2)+C FET 210(2))*input voltage V_{IN}, wherein ‘C’ is capacitance. In this example, the first varactor 218(1) and the first FET 210(1) have the same thin-gate insulator, and the second varactor 218(2) and the second FET 210(2) have the same thin-gate insulator. Thus, the gate voltages V_{G1}, V_{G2} will be equal to the respective varactor voltages V_{V1}, V_{V2} of the respective first and second varactors 218(1), 218(2) based on the input voltage V_{IN} being divided evenly between the first FET 210(1) and the first varactor 218(1), and also being divided evenly between the second FET 210(2) and the second varactor 218(2). Thus, also in this example, for a direct current (DC) input signal 204, the leakage current Ig-_{F1} of the first FET 210 (1)=the leakage current Ig-ᵥ₁ of the first varactor 218(1), and the leakage current of the second FET 210(2) Ig-_{F2}=the leakage current Ig-ᵥ₂ of the second varactor 218(2). Since the first varactor 218(1) and the first FET 210(1) have the same thin-gate insulator, and the second varactor 218(2) and the second FET 210(2) have the same thin-gate insulator in this example, the input voltage V_{IN} will be divided evenly between the first FET 210(1) and the first varactor 218(1), and also divided evenly between the second FET 210(2) and the second varactor 218(2), for both an AC and DC input signal 204.

In this manner, the gate voltage V_{G1}, V_{G2} can be provided within the breakdown voltages of the first and second FETs 210(1), 210(2), but the first and second FETs 210(1), 210(2) being series coupled to each other allows the output signal 208 generated on the output node 206 to be in the voltage domain and voltage range of the supply voltage V_{DD}. Thus, the electronic device 200 will have an effective overall breakdown voltage that is at least the supply voltage V_{DD} and greater than the breakdown voltage of the individual first and second FETs 210(1), 210(2). In this manner, the electronic device 200 can be provided that has the single input node 202 without the requirement for voltage level shifting of the input signal 204 and without the need for additional FETs to apply offset voltages to the first and second FETs 210(1), 210(2) like the electronic device 100 in FIG. 1.

Also note that because of the inclusion of the series connected first and second varactors 218(1), 218(2) between the input node 202 and the respective first and second FETs 210(1), 210(2), the first and second varactors 218(1), 218(2) can also be provided as thin-gate insulator devices similar to the first and second FETs 210(1), 210(2) and also discussed with regard to FIG. 2A-1. This is because the division of the input voltage V_{IN} across the first varactor 218(1) and its coupled first FET 210(1), and across the second varactor 218(2) and is coupled second FET 210(2) also reduces the voltage across the first and second varactors 218(1), 218(2). Thus, the first and second varactors 218(1), 218(2) can be designed with thinner gate insulators 232 (see FIG. 2A-1) that provide for their having lower breakdown voltages than the supply voltage V_{DD}. Also note that by inclusion of the series connected first and second varactors 218(1), 218(2) between the input node 202 and the respective first and second FETs 210(1), 210(2), the first and second FETs 210(1), 210(2) are also electrically isolated from the input node 202. This may have the benefit of reducing leakage voltage of the first and second FETs 210(1), 210(2) when the input signal 204 is inactive or does not have a sufficient input voltage V_{IN} that when divided, activates (exceed the threshold voltage) the first and second FETs 210(1), 210(2).

FIG. 2B is a circuit layout diagram of an electronic device 200(1) that has a circuit arrangement like the electronic device 200 in FIGS. 2A-1 and 2A-2 wherein the first and second varactors 218(1), 218(2) are P-type semiconductor (P)+/P-well varactors 218P(1), 218P(2) each coupled in series to respective N-type semiconductor (N) field-effect transistors (NFETs) 210N(1), 210N(2) as the first and second FETs 210(1), 210(2). For example, the common circuit elements between the electronic device 200 in FIGS. 2A-1 and 2A-2 and the electronic device 200(1) in FIG. 2B are shown with common element numbers.

In this regard, as shown in FIG. 2B, the electronic device 200(1) includes a first circuit 240(1) that includes a first diffusion region 242, which is a P+ implant diffusion region 242P (“P diffusion region 242P”) in this example, and a second diffusion region 244, which is an N+ implant diffusion region 244N (“N diffusion region 244N”) and opposite polarity of the P diffusion region 242P in this example. The first circuit 240(1) can be a cell circuit that is provided in a standard cell as a non-limiting example. The P and N diffusion regions 242P, 244N are disposed on a P-well substrate 246P (P-well 246) in this example. The first and second varactors 218P(1), 218P(2) are both formed in the P diffusion region 242P as P+/P-well varactors. The first and second varactors 218P(1), 218P(2) have respective first and second anodes 234P(1), 234P(2) and first and second cathodes 236P(1), 236P(2). The first and second NFETs 210N(1), 210N(2) are both formed in the N diffusion region 244N. The first NFET 210N(1) has the first gate G₁, the first terminal S₁, which is the first source S₁, and the second terminal D₁, which is the first drain D₁. The first gate G₁ is an active portion of a first gate structure 248(1) that intersects with a semiconductor channel 212P (“channel 212P”) in the N diffusion region 244N. The second NFET 210N(2) has the second gate G₂, the third terminal S₂, which is the second source S₂, and the fourth terminal D₂, which is the second drain D₂. The second gate G₂ is an active portion of a second gate structure 248(2) that intersects with the semiconductor channel 212P in the N diffusion region 244N. In this example, and as shown in FIGS. 2A-1 and 2A-2, the first drain D₁ of the first NFET 210N(1) is coupled to the second source S₂ of the second NFET 210N(1) to form the output node 206.

With continuing reference to FIG. 2B, the first and second gate structures 248(1), 248(2) both extend in the first and second diffusion regions 242P, 244N in a first direction (Y-axis direction) without gate cuts. In this manner, the first and second gate structures 248(1), 248(2) provide a coupling between the respective first and second cathodes 236P(1), 236P(2) of the respective first and second varactors 218P(1), 218P(2) in the P diffusion region 242P, and the respective first and second gates G₁, G₂ of the respective first and second NFETs 210N(1), 210N(2). Further, as shown in FIG. 2B, the input node 202 in this example is formed by a first metal line 250 in a first metal layer 252 (e.g. MO layer) that extends in the channel 212P direction (X-axis direction) and is coupled to first and second contacts 254P(1), 254P(2) coupled to the respective first and second anodes 234P(1), 234P(2) of the first and second varactors 218P(1), 218P(2).

FIG. 2C is a circuit layout diagram of another electronic device 200(2) that has a circuit arrangement like the electronic devices 200, 200(1) in FIGS. 2A-1-2A-2 and 2B, but wherein the first and second varactors 218(1), 218(2) are N+/N-well varactors 218N(1), 218N(2) each coupled in series to respective PFETs 210P(1), 210P(2) as the first and second FETs 210(1), 210(2). Common elements between the electronic devices 200, 200(1) in FIGS. 2A-1-2A-2 and 2B and the electronic device 200(2) in FIG. 2C are shown with common element numbers.

In this regard, as shown in FIG. 2C, the electronic device 200(2) includes a first circuit 240(2) that includes a first diffusion region 242, which is a N+ implant diffusion region 242N (“N diffusion region 242N”) in this example, and a second diffusion region 244, which is a P+ implant diffusion region 244P (“P diffusion region 244P”) and opposite polarity of the N diffusion region 242N in this example. The first circuit 240(2) can be a cell circuit that is provided in a standard cell as a non-limiting example. The N and P diffusion regions 242N, 244P are disposed on an N-well substrate 246N (N-well 246N) in this example. The first and second varactors 218N(1), 218N(2) are both formed in the N diffusion region 242N as N+/N-well varactors. The first and second varactors 218N(1), 218N(2) have respective first and second anodes 234N(1), 234N(2) and first and second cathodes 236N(1), 236N(2). The first and second PFETs 210P(1), 210P(2) are both formed in the P diffusion region 244P. The first PFET 210P(1) has the first gate G₁, the first terminal S₁, which is the first source S₁, and the second terminal D₁, which is the first drain D₁. The first gate G₁ is an active portion of a first gate structure 248(1) that intersects with a semiconductor channel 212N in the P diffusion region 244P. The second PFET 210P(2) has the second gate G₂, the third terminal S₂, which is the second source S₂, and the fourth terminal, which is the second drain D₂. The second gate G₂ is an active portion of a second gate structure 248(2) that intersects with the semiconductor channel 212N in the P diffusion region 244P. In this example, and as shown in FIGS. 2A-1 and 2A-2, the first drain D₁ of the first PFET 210P(1) is coupled to the second source S₂ of the second PFET 210P(1) to form the output node 206.

With continuing reference to FIG. 2C, the first and second gate structures 248(1), 248(2) both extend in the first and second diffusion regions 242N, 244P in a first direction (Y-axis direction) without gate cuts. In this manner, the first and second gate structures 248(1), 248(2) provide a coupling between the respective first and second cathodes 236N(1), 236N(2) of the respective first and second varactors 218N(1), 218N(2) in the N diffusion region 242N, and the respective first and second gates G₁, G₂ of the respective first and second PFETs 210P(1), 210P(2). Further, as shown in FIG. 2C, the input node 202 in this example is formed by the first metal line 250 in the first metal layer 252 (e.g. MO layer) that extends in the channel 212N direction (X-axis direction) and is coupled to first and second contacts 254N(1), 254N(2) coupled to the respective first and second anodes 234P(1), 234P(2) of the first and second varactors 218P(1), 218P(2).

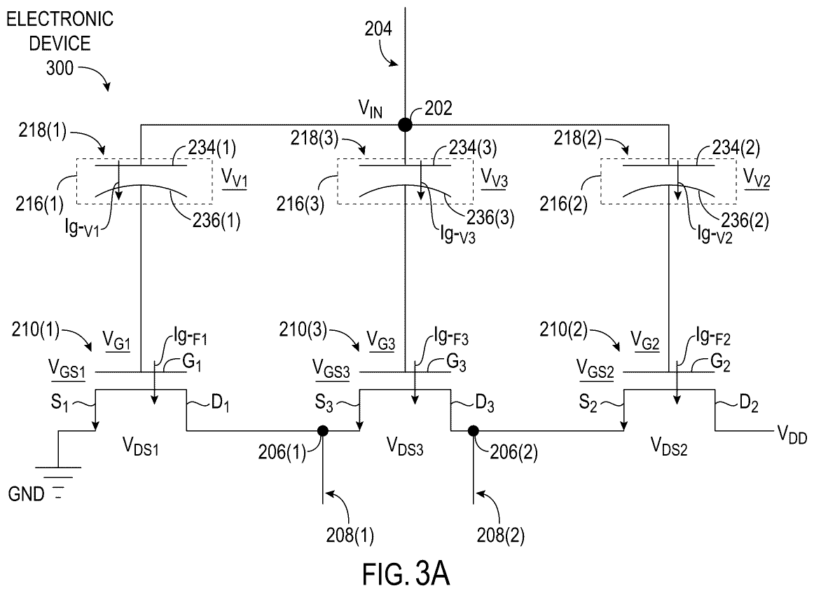

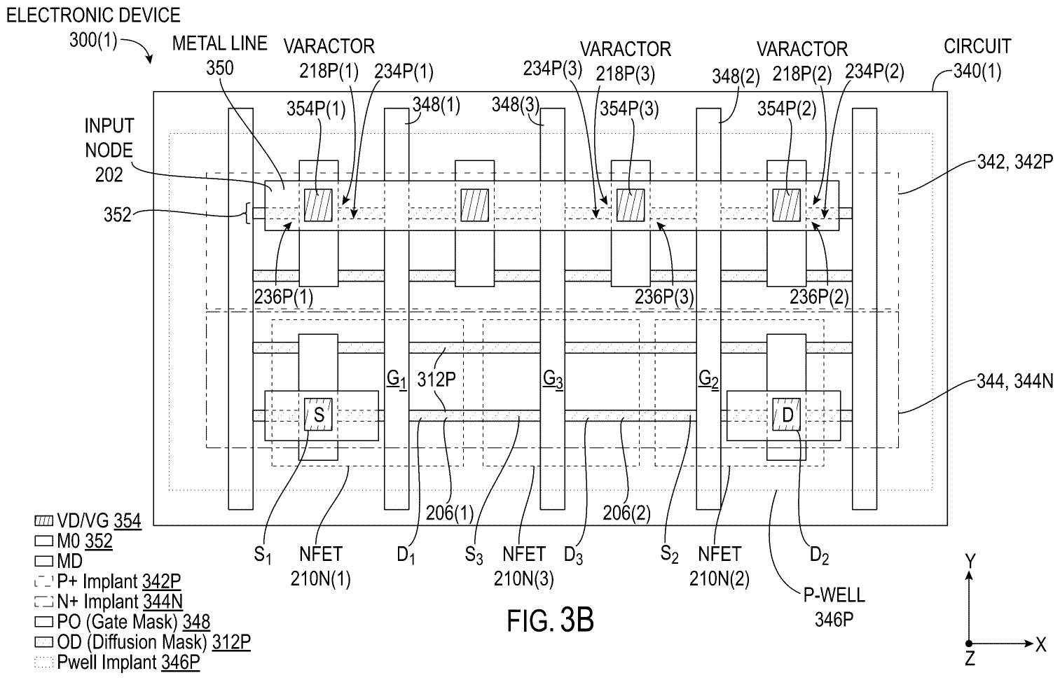

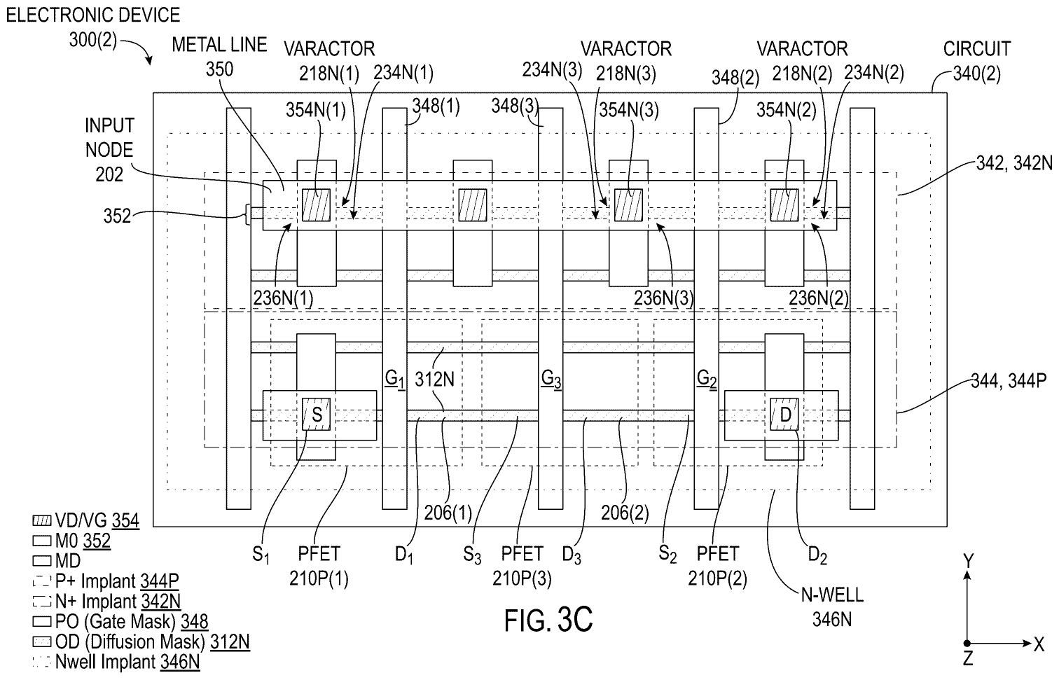

FIG. 3A is circuit diagram of another three (3) terminal electronic device 300 that includes the single input node 202 configured to receive an input signal 204, and output nodes 206(1), 206(2). Common elements between the electronic device 200 in FIGS. 2A-1 and 2A-2 and the electronic device 300 in FIG. 3A are shown with common element numbers.

In this regard, as shown in FIG. 3A, the electronic device 300 includes the single input node 202 configured to receive the input signal 204 and is configured to generate an output signal 208(1), 208(2) on a respective first and second output node 206(1), 206(2) based on the input signal 204 in the voltage domain and voltage range of the supply voltage V_{DD}. However, in this example, three (3) FETs 210(1)-210(3) are provided and coupled to each other in series between the first terminal S₁ of the first FET 210(1) coupled to ground GND and the fourth terminal D₂ of the second FET 210(2) configured to receive the supply voltage V_{DD}. In this regard, the electronic device 300 includes a third FET 210(3) that includes a third gate G₃, a fifth terminal S₃, which is a third source S₃, and a sixth terminal D₃, which is a third drain D₃. The third FET 210(3) can be designed like and have the same properties of the first and/or second FETs 210(1), 210(2).

Like the electronic device 200 in FIGS. 2A-1 and 2A-2, to avoid the need for additional FETs to provide offset voltages and synchronized voltage level shifted input signals in the electronic device 300, the electronic device 300 includes the first, second, and third varactor circuits 216(1)-216(3), which in this example are respective first, second, and third varactors 218(1)-218(3). The varactors 218(1)-218(3) are each coupled in series between the respective gates G₁, G₂, G₃ of the first, second, and third FETs 210(1)-210(3) and the input node 202 to support the single input signal 204 for the electronic device 300. Each respective varactor 218(1)-218(3) that is series coupled to a respective FET 210(1)-210(3) is coupled to the input node 202 in parallel to each other. The varactors 218(1)-218(3) create a voltage division of the input voltage V_{IN} of the input signal 204 between the respective varactors 218(1)-218(3) and their respective series connected gates G₁, G₂, G₃ of the FETs 210(1)-210(3). This reduces respective gate-to-source voltages V_{GS1}, V_{GS2}, V_{GS3} of the FETs 210(1)-210(3) to prevent the input voltage V_{IN} of the input signal 204 in the voltage domain of the supply voltage V_{DD} from causing the gate-to-source voltages V_{GS1}, V_{GS2}, V_{GS3}, and the drain-to-source voltages V_{DS1}, V_{DS2} V_{DS3} of the FETs 210(1)-210(3) to exceed their respective breakdown voltages.

Providing the varactors 218(1)-218(3) series connected between the input node 202 and the respective FETs 210(1)-210(3) allows the electronic device 300 to be powered by a higher supply voltage V_{DD} than the breakdown voltage of the FETs 210(1)-210(3). The need to provide voltage shifting to provide multiple, synchronized input signals and added FETs to provide fixed offset voltages to avoid exceeding the breakdown voltages of the first FETs 210(1)-210(3) can be avoided. As an example, the electronic device 300 can be employed in applications that have larger supply voltages, such as I/O circuits or ESD circuits, for example, but using the FETs 210(1)-210(3) that have a voltage breakdown less than the supply voltage. This allows the FETs 210(1)-210(3) employed in the electronic device 300 to be thin-gate insulator FETs that have a reduced breakdown voltage, but provide the benefits of reduced SCEs and/or area. Also, the inclusion of the series coupled varactors 218(1)-218(3) in the electronic device 300 provides signal isolation between the input node 202 and the gates G₁, G₂, G₃ of the respective FETs 210(1)-210(3). Thus, the gates G₁, G₂, G₃ of the respective FETs 210(1)-210(3) are floating when no input signal 204 is applied to the input node 202 to reduce or avoid current leakage in the electronic device 300.

With continued reference to FIG. 3A, the electronic device 300 includes the FETs 210(1)-210(3) that have the respective first, second, and third gates G₁, G₂, G₃. The first FET 210(1) has the first and second terminals S₁, D₁, the second FET 210(2) has the third and fourth terminals S₂, D₂, and the third FET 210(3) has the fifth and sixth terminals S₃, D₃. In this example, the first, third, and fifth terminals S₁, S₂, S₃, are first, second, and third sources S₁, S₂, S₃, and the second, fourth, and sixth terminals D₁, D₂, D₃ are first, second, and third drains D₁, D₂, D₃ but the terminals could be source/drain or drain/source interchangeably. The FETs 210(1)-210(3) have respective breakdown voltages for their gate-to-source voltages V_{GS1}, V_{GS2}, V_{GS3} that are dictated by the thickness of the gate insulators between their respective gates G₁, G₂, G₃ and their channels (see, e.g., channel 212 in FIG. 2A-1). The FETs 210(1)-210(3) also have respective breakdown voltages for their drain-to-source voltages V_{DS1}, V_{DS2}, V_{DS3} that are dictated by the thickness of the gate insulators between their respective gates G₁, G₂, G₃ and their channels (see, e.g., channel 212 in FIG. 2A-1).

With continuing reference to FIG. 3A, the FETs 210(1)-210(3) are series connected (also referred to as “stacked FETs”) in that the first drain D₁ of the first FET 210(1) is coupled to the third source S₃ of the third FET 210(3), and the third drain D₃ of the third FET 210(3) is coupled to the second source S₂ of the second FET 210(2). The first output node 206(1) is formed as the node coupled to the first drain D₁ of the first FET 210(1). Or, the output node 206(2) can be the node coupled to the third drain D₃ of the third FET 210(3). The electronic device 300 is powered by a supply voltage V_{DD} that is connected to the second drain D₂ of the second FET 210(2), with the first source S₁ of the first FET 210(1) coupled to ground GND, which is 0 V with respect to the supply voltage V_{DD}. Thus, the supply voltage V_{DD} is applied across the three FETs 210(1)-210(3) coupled in series together. The electronic device 300 is configured to generate the output signal 208(1), 208(2) on the respective first and second output node 206(1), 206(2) in the voltage domain of the supply voltage V_{DD} based on the voltage of the input signal 204 applied to the input node 202.

With continuing reference to FIG. 3A, the electronic device 300 also includes the first, second, and third varactor circuits 216(1), 216(2), 216(3), which in this example are the respective first, second, and third varactors 218(1)-218(3). The third varactor 218(3) includes a third anode 234(3) coupled to the input node 202, and a third cathode 236(3) coupled to the third gate G₃ of the third FET 210(3). Thus, the input node 202 in this example is coupled in parallel to the first, second, and third anodes 234(1)-234 (3) of the respective first, second, and third varactors 218(1)-218(3). Thus, with the presence of the varactors 218(1)-218(3) coupled in series to and between the input node 202 and the respective FETs 210(1)-210(3), a voltage division of the input voltage V_{IN} occurs. The input voltage VINis divided between the respective varactors 218(1)-218(3) and their respective series coupled FETs 210(1)-210(3) based on the relative impedances of the respective varactors 218(1)-218(3) and their series coupled FETs 210(1)-210(3). In this manner, an input signal 204 having the input voltage V_{IN} in the voltage domain and voltage range of the supply voltage V_{DD} is not directly applied to the gates G₁, G₂, G₃ of the respective FETs 210(1)-210(3). A reduced gate voltage V_{G1}, V_{G2}, V_{G3}, of the input voltage V_{IN} is applied to the gates G₁, G₂, G₃ of the respective FETs 210(1)-210(3).

In this example electronic device 300 in FIG. 3A, for an AC input signal 204, the gate voltage V_{G1}=C varactor 218(1)/(C varactor 218(1)+C FET 210(1))*input voltage V_{IN}, the gate voltage V_{G2}=C varactor 218(2)/(C varactor 218(2)+C FET 210(2))*input voltage V_{IN}, and the gate voltage V_{G3}=C varactor 218(3)/(C varactor 218(3)+C FET 210(3))*input voltage V_{IN}, wherein ‘C’ is capacitance. In this example, the first varactor 218(1) and the first FET 210(1) have the same thin-gate insulator, the second varactor 218(2) and the second FET 210(2) have the same thin-gate insulator, and the third varactor 218(3) and the third FET 210(3) have the same thin-gate insulator. Thus, the gate voltages V_{G1}, V_{G2}, V_{G3} will equal to the respective varactor voltages V_{V1}, V_{V2}, V_{V3} of the respective first, second, and third varactors 218(1)-218(3) based on the input voltage V_{IN} being divided evenly between the first FET 210(1) and the first varactor 218(1), being divided evenly between the second FET 210(2) and the second varactor 218(2), and being divided evenly between the third FET 210(3) and the third varactor 218(3). Thus, also in this example, for a DC input signal 204, the leakage current Ig-_{F1} of the first FET 210(1)=the leakage current Ig-ᵥ₁ of the first varactor 218(1), the leakage current of the second FET 210(2) Ig-_{F2}=the leakage current Ig-_{V2} of the second varactor 218(2), and the leakage current of the third FET 210(3) Ig-_{F3}=the leakage current Ig-_{V3} of the third varactor 218(3). Since the first varactor 218(1) and the first FET 210(1) have the same thin-gate insulator, the second varactor 218(2) and the second FET 210(2) have the same thin-gate insulator, and the third varactor 218(3) and the third FET 210(3) have the same thin-gate insulator in this example, the input voltage V_{IN} will be divided evenly between the first FET 210(1) and the first varactor 218(1), divided evenly between the second FET 210(2) and the second varactor 218(2), and divided evenly between the third FET 210(3) and the third varactor 218(3), for both an AC and DC input signal 204. In this manner, the gate voltages V_{G1}, V_{G2}, V_{G3} can be provided within the breakdown voltages of the respective FETs 210(1)-210(3), but the FETs 210(1)-210(3) being series coupled to each other allows the output signals 208(1), 208(2) generated on the output nodes 206(1), 206(2) to be in the voltage domain and voltage range of the supply voltage V_{DD}. Thus, the electronic device 300 will have an effective overall breakdown voltage that is at least the supply voltage V_{DD} and greater than the breakdown voltage of the individual FETs 210(1)-210(3). In this manner, the electronic device 300 can be provided that has the single input node 202 without the requirement for voltage level shifting of the input signal 204 and without the need for additional FETs to apply offset voltages to the FETs 210(1)-210(3) like the electronic device 100 in FIG. 1.

Also note that because of the inclusion of the series connected varactors 218(1)-218(3) between the input node 202 and the respective FETs 210(1)-210(3), the varactors 218(1)-218(3) can also be provided as thin-gate insulator devices similar to the FETs 210(1)-210(3) and also discussed with regard to FIG. 2A-1. This is because the division of the input voltage V_{IN} across the varactors 218(1)-218(3) and their respective coupled FETs 210(1)-210(3), reduces the voltage across the varactors 218(1)-218(3). Thus, the varactors 218(1)-218(3) can be designed with thinner gate insulators 232 (see FIG. 2A-1) that provide for their having lower breakdown voltages than the supply voltage V_{DD}. Also note that by inclusion of the series connected varactors 218(1)-218(3) between the input node 202 and the respective FETs 210(1)-210(3), the FETs 210(1)-210(3) are also electrically isolated from the input node 202. This may have the benefit of reducing leakage voltage of the FETs 210(1)-210(3) when the input signal 204 is inactive or does not have a sufficient input voltage V_{IN} that when divided, activates (exceeds the threshold voltage) the FETs 210(1)-210(3).

FIG. 3B is a circuit layout diagram of an electronic device 300(1) that has a circuit arrangement like the electronic device 300 in FIG. 3A, wherein the varactors 218(1)-218(3) are P-type semiconductor (P)+/P-well varactors 218P(1)-218P (3) each coupled in series to respective NFETs 210N(1)-210N(3) as the FETs 210(1)-210(3). Common elements between the electronic device 300 in FIG. 3A and the electronic device 300(1) in FIG. 3B are shown with common element numbers.

In this regard, as shown in FIG. 3B, the electronic device 300(1) includes a first circuit 340(1) that includes a first diffusion region 342, which is a P+ implant diffusion region 342P (“P diffusion region 342P”) in this example, and a second diffusion region 344, which is an N+ implant diffusion region 344N (“N diffusion region 344N”) and opposite polarity of the P diffusion region 342P in this example. The first circuit 340(1) can be a cell circuit that is provided in a standard cell as a non-limiting example. The P and N diffusion regions 342P, 344N are disposed on a P-well substrate 346P (P-well 346P) in this example. The varactors 218P(1)-218P (3) are each formed in the P diffusion region 342P as P+/P-well varactors. The varactors 218P(1)-218P (3) have respective first, second, and third anodes 234P(1)-234P (3) and first, second, and third cathodes 236P(1)-236P (3). The first, second, and third NFETs 210N(1), 210N(2), 210N(3) are each formed in the N diffusion region 344N. The first NFET 210N(1) has the first gate G₁, the first terminal S₁, which is the first source S₁, and the second terminal D₁, which is the first drain D₁. The first gate G₁ is an active portion of a first gate structure 348(1) that intersects with a semiconductor channel 312P in the N diffusion region 344N. The second PFET 210N(2) has the second gate G₂, the third terminal S₂, which is the second source S₂, and the fourth terminal, which is the second drain D₂. The second gate G₂ is an active portion of a second gate structure 348(2) that intersects with the semiconductor channel 312P in the N diffusion region 344N. The third PFET 210N(3) has the third gate G₃, the fifth terminal S₃, which is the third source S₃, and the sixth terminal D₃, which is the third drain D₃. The third gate G₃ is an active portion of a third gate structure 348(3) that intersects with the semiconductor channel 312P in the N diffusion region 344N. In this example, the first drain D₁ of the first NFET 210N(1) is coupled to the third source S₃ of the third NFET 210N(3) to form the first output node 206(1). The third drain D₃ of the third NFET 210N(3) is coupled to the second source S₂ of the second NFET 210N(2) to form the second output node 206(2).

With continuing reference to FIG. 3B, the first, second, and third gate structures 348(1), 348(2), 348(3) both extend in the first and second diffusion regions 342P, 344N in a first direction (Y-axis direction) without gate cuts. In this manner, the gate structures 348(1)-348(3) provide a coupling between the respective cathodes 236P(1)-236P (3) of the respective varactors 218P(1)-218P (3) in the P diffusion region 342P, and the respective gates G₁, G₂, G₃ of the respective NFETs 210N(1)-210N(3). Further, as shown in FIG. 3B, the input node 202 in this example is formed by a first metal line 350 in a first metal layer 352 (e.g. MO layer) that extends in the channel 312P direction (X-axis direction) and is coupled to first, second, and third contacts 354P(1), 354P(2), 354P (3) coupled to the respective anodes 234P(1)-234P (3) of the respective varactors 218P(1)-218P (3).

FIG. 3C is a circuit layout diagram of another electronic device 300(2) that has a circuit arrangement like the electronic devices 300, 300(1) in FIGS. 3A and 3B, but wherein the varactors 218(1)-218(3) are N+/N-well varactors 218N(1)-218N(3) each coupled in series to respective PFETs 210P(1)-210P (3) as the FETs 210(1)-210(3). Common elements between the electronic devices 300, 300(1) in FIGS. 3A and 3B and the electronic device 300(2) in FIG. 3B are shown with common element numbers.

In this regard, as shown in FIG. 3C, the electronic device 300(2) includes a first circuit 340(2) that includes a first diffusion region 342, which is an N+ implant diffusion region 342N (“N diffusion region 342N”) in this example, and a second diffusion region 344, which is a P+ implant diffusion region 344P (“P diffusion region 344P”) and opposite polarity of the N diffusion region 342N in this example. The first circuit 340(2) can be a cell circuit that is provided in a standard cell as a non-limiting example. The N and P diffusion regions 342N, 344P are disposed on an N-well substrate 346N (N-well 346N) in this example. The varactors 218N(1)-218N(3) are each formed in the N diffusion region 342N as N+/N-well varactors. The varactors 218N(1)-218N(3) have respective first, second, and third anodes 234N(1)-234N(3) and first, second, and third cathodes 236N(1)-236N(3). The first, second, and third PFETs 210P(1), 210P(2), 210P (3) are each formed in the P diffusion region 344P. The first PFET 210P(1) has the first gate G₁, the first terminal S₁, which is the first source S₁, and the second terminal D₁, which is the first drain D₁. The first gate G₁ is an active portion of the first gate structure 348(1) that intersects with a semiconductor channel 312N in the P diffusion region 344P. The second PFET 210P(2) has the second gate G₂, the third terminal S₂, which is the second source S₂, and the fourth terminal D₂, which is the second drain D₂. The second gate G₂ is an active portion of the second gate structure 348(2) that intersects with the semiconductor channel 312N in the P diffusion region 344P. The third PFET 210P (3) has the third gate G₃, the fifth terminal S₃, which is the third source S₃, and the sixth terminal D₃, which is the third drain D₃. The third gate G₃ is an active portion of the third gate structure 348(3) that intersects with the semiconductor channel 312N in the P diffusion region 344P. In this example, the first drain D₁ of the first PFET 210P(1) is coupled to the third source S₃ of the third PFET 210P (3) to form the first output node 206(1). The third drain D₃ of the third PFET 210P (3) is coupled to the second source S₂ of the second PFET 210P(2) to form the second output node 206(2).

With continuing reference to FIG. 3C, the first, second, and third gate structures 348(1), 348(2), 348(3) both extend in the first and second diffusion regions 342N, 344P in a first direction (Y-axis direction) without gate cuts. In this manner, the gate structures 348(1)-348(3) provide a coupling between the respective cathodes 236N(1)-236N(3) of the respective varactors 218N(1)-218N(3) in the N diffusion region 342N, and the respective gates G₁, G₂, G₃ of the respective PFETs 210P(1)-210P (3). Further, as shown in FIG. 3C, the input node 202 in this example is formed by the first metal line 350 in the first metal layer 352 (e.g., MO layer) that extends in the channel 312N direction (X-axis direction) and is coupled to first, second, and third contacts 354N(1), 354N(2), 354N(3) coupled to the respective anodes 234N(1)-234N(3) of the respective varactors 218N(1)-218N(3).

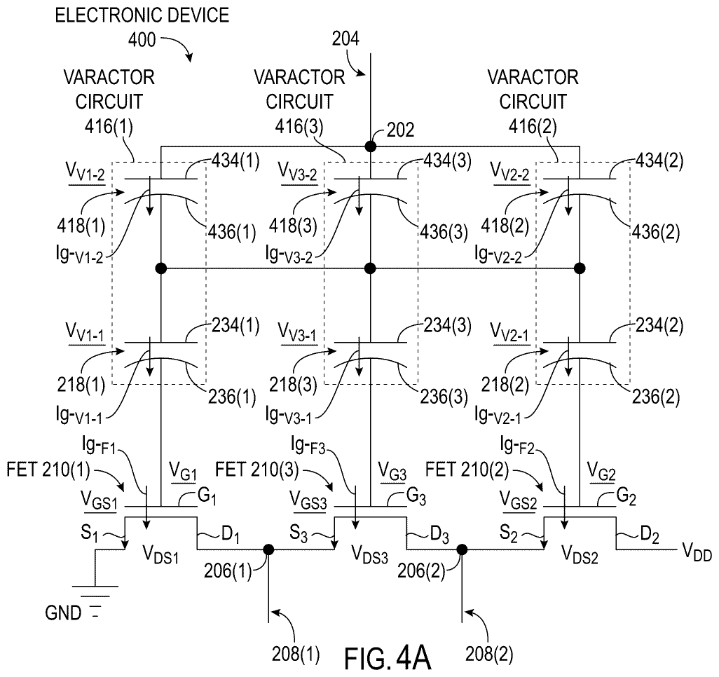

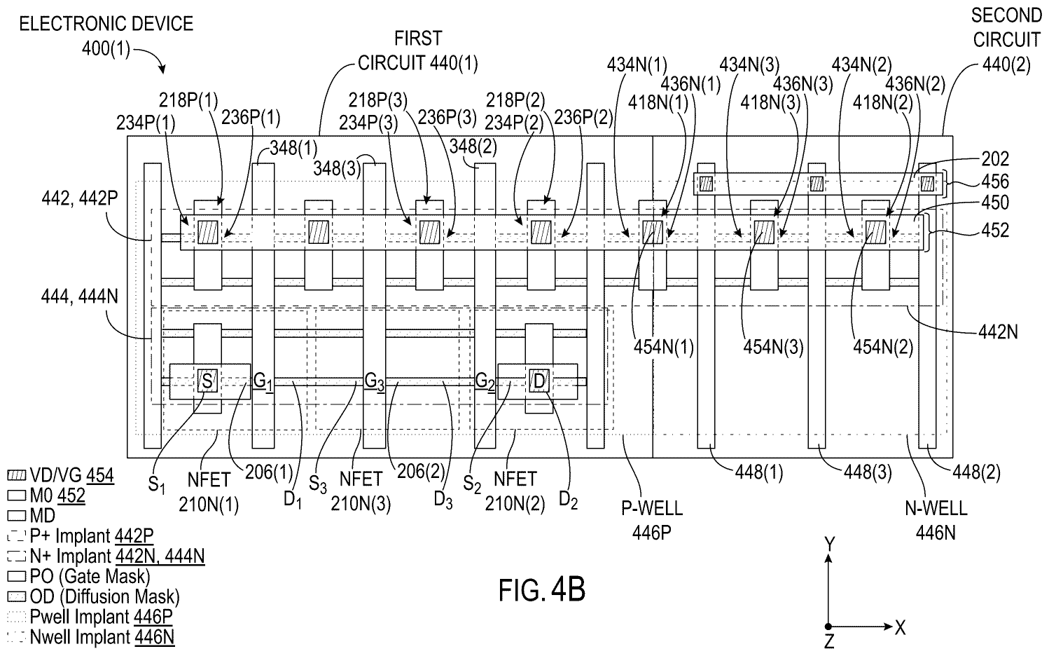

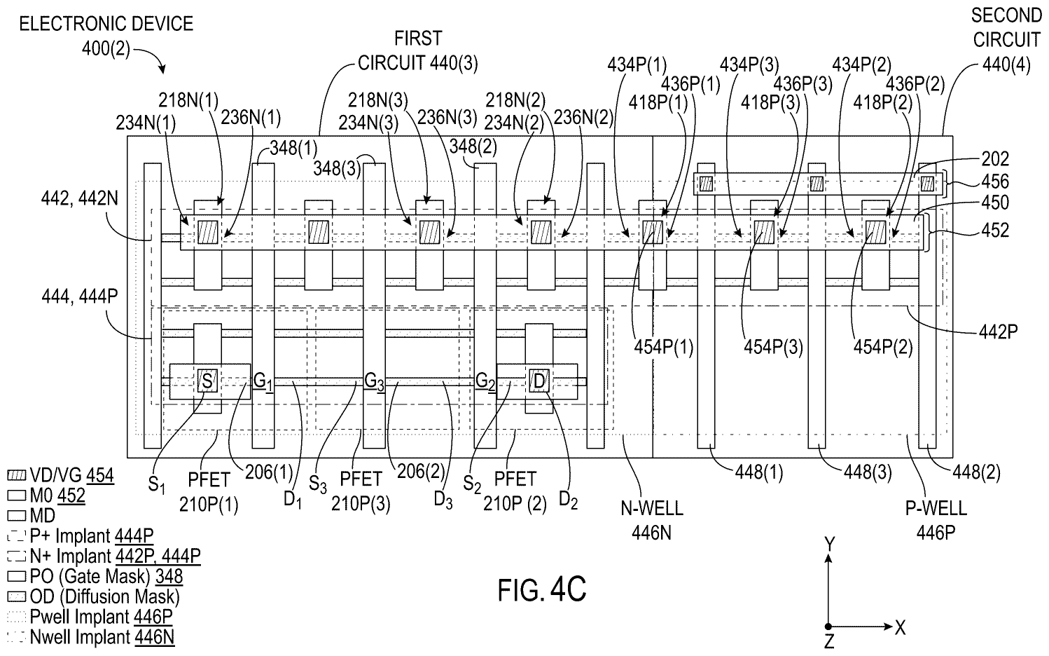

FIG. 4A is a circuit diagram of an exemplary three (3) terminal electronic device 400 that includes three (3) varactor circuits 416(1)-416(3) similar to the varactor circuits 216(1)-216(3) in the electronic device 300 in FIG. 3A. However, in the electronic device 400 in FIG. 4A, each varactor circuit 416(1)-416(3) includes two (2) series coupled respective varactors 218(1) and 418(1), 218(2) and 418(2), 218(3) and 418(3) to provide a voltage divider of the input signal V_{IN} between each varactor circuit 416(1)-416(3) and its respective series coupled gates G₁, G₂, G₃ of the FETs 210(1)-210(3). Common elements between the electronic device 400 in FIG. 4A and the electronic devices 200, 300 in FIGS. 2A-1, 2A-2, and 3A are shown with common element numbers.

In this regard, as shown in FIG. 4A, the electronic device 400 includes the single input node 202 configured to receive the input signal 204 and is configured to generate the output signal 208(1), 208(2) on a respective first and second output node 206(1), 206(2) based on the input signal 204 in the voltage domain and voltage range of the supply voltage V_{DD}. However, in this example, the varactor circuits 416(1)-416(3) each include two series coupled varactors. The first varactor circuit 416(1) includes two (2) varactors: the first varactor 218(1) and a fourth varactor 418(1) coupled in series together. The second varactor circuit 416(2) includes two (2) varactors: the second varactor 218(2) and a fifth varactor 418(2) coupled in series together. The third varactor circuit 416(3) includes two (2) varactors: the third varactor 218(3) and a sixth varactor 418(3) coupled in series together. Like in the electronic device 300 in FIG. 3A, the varactors 218(1)-218(3) in the electronic device 400 in FIG. 4A are each coupled to the respective gates G₁, G₂, G₃ of the first, second, and third FETs 210(1)-210(3). However, in the electronic device 400 in FIG. 4A, the additional varactors 418(1)-418(3) are coupled to the input node 202. Providing the additional varactors 418(1)-418(3) in the respective varactor circuits 416(1)-416(3) further divides the input voltage V_{IN} to further reduce the respective gate-to-source voltages V_{GS1}, V_{GS2}, V_{GS3} of the FETs 210(1)-210(3). This can prevent the input voltage V_{IN} of the input signal 204 in the voltage domain of the supply voltage V_{DD} from causing the gate-to-source voltages V_{GS1}, V_{GS2}, V_{GS3}, and the drain-to-source voltages V_{DS1}, V_{DS2} V_{DS3} of the FETs 210(1)-210(3) to exceed their respective breakdown voltages.

With continuing reference to FIG. 4A, the fourth varactor 418(1) includes a fourth anode 434(1) coupled to the input node 202, and a fourth cathode 436(1) coupled to the first anode 234(1) of the first varactor 218(1). The fifth varactor 418(2) includes a fifth anode 434(2) coupled to the input node 202, and a fifth cathode 436(2) coupled to the second anode 234(2) of the second varactor 218(2). The sixth varactor 418(3) includes a sixth anode 434(3) coupled to the input node 202, and a sixth cathode 436(3) coupled to the third anode 234(3) of the third varactor 218(3). Thus, the input node 202 in this example is coupled in parallel to the first, second, and third varactor circuits 416(1)-416(3). Thus, with the presence of the varactor circuits 416(1)-416(3) coupled in series to and between the input node 202 and the respective FETs 210(1)-210(3), a voltage division of the input voltage V_{IN} occurs. The input voltage V_{IN} is divided between the respective varactor circuits 416(1)-416(3) and their respective varactors 218(1), 418(1); (2), 418(2); 218(3), 418(3) and their respective series coupled FETs 210(1)-210(3) based on the relative impedances of the respective varactors 218(1), 418(1); 218(2), 418(2); 218(3), 418(3) and their series coupled FETs 210(1)-210(3). In this manner, an input signal 204 having the input voltage V_{IN} in the voltage domain and voltage range of the supply voltage V_{DD} is not directly applied to the gates G₁, G₂, G₃ of the respective FETs 210(1)-210(3). A reduced gate voltage V_{G1}, V_{G2}, V_{G3}, of the input voltage V_{IN} is applied to the gates G₁, G₂, G₃ of the respective FETs 210(1)-210(3).

In this example electronic device 400 in FIG. 4A, for an AC input signal 204, the gate voltage V_{G1}=C varactor 218(1)*C varactor 418(1)/(C FET 210(1)*C varactor 218 (1)+C FET 210(1)*C varactor 418 (1)+C varactor 218(1)*C varactor 418(1))*input voltage V_{IN}, wherein ‘C’ is capacitance. Similarly, the gate voltage V_{G2}=C varactor 218(2)*C varactor 418(2)/(C FET 210(2)*C varactor 218 (2)+C FET 210(2)*C varactor 418(2)+C varactor 218(2)*C varactor 418(2))*input voltage V_{IN}, wherein ‘C’ is capacitance. Similarly, the gate voltage V_{G3}=C varactor 218(3)*C varactor 418(3)/(C FET 210(3)*C varactor 218(3)+C FET 210(3)*C varactor 418 (3)+C varactor 218(3)*C varactor 418(3))*input voltage V_{IN}, wherein ‘C’ is capacitance. In this example, the first varactor 218(1), the fourth varactor 418(1), and the first FET 210(1) have the same thin-gate insulator. Thus, the gate voltage V_{G1} will be equal to the respective varactor voltages V_{V1-1} and V_{V1-2} of the respective first and fourth varactors 218(1), 418(1) based on the input voltage V_{IN} being divided evenly between the first FET 210(1), the first varactor 218(1), and the fourth varactor 418(1). Also, in this example, the second varactor 218(2), the fifth varactor 418(2), and the second FET 210(2) have the same thin-gate insulator. Thus, the gate voltage V_{G2} will be equal to the respective varactor voltages V_{V2-1} and V_{V2-2} of the respective second and fifth varactors 218(2), 418(2) based on the input voltage V_{IN} being divided evenly between the second FET 210(2), the second varactor 218(2), and the fifth varactor 418(2). Also, in this example, the third varactor 218(3), the sixth varactor 418(3), and the third FET 210(3) have the same thin-gate insulator. Thus, the gate voltage V_{G3} will be equal to the respective varactor voltages V_{V3-1} and V_{V3-2} of the respective third and sixth varactors 218(3), 418(3) based on the input voltage V_{IN} being divided evenly between the third FET 210(3), the third varactor 218(3), and the sixth varactor 418(3).

Thus, also in this example, for a DC input signal 204, the leakage current Ig-_{F1} of the first FET 210(1)=the leakage current Ig-_{V1-1} of the first varactor 218(1) and the leakage current Ig-_{V1-2} of the fourth varactor 418(1). The leakage current Ig-_{F2} of the second FET 210(2)=the leakage current Ig-_{V2-1} of the second varactor 218(2) and the leakage current Ig-_{V2-2} of the fifth varactor 418(2). The leakage current Ig-_{F3} of the third FET 210(3)=the leakage current Ig-_{V3-1} of the third varactor 218(3) and the leakage current Ig-_{V3-2} of the sixth varactor 418(3). Since the first and fourth varactors 218(1), 418(1) and the first FET 210(1) have the same thin-gate insulator, the second and fifth varactors 218(2), 418(2) and the second FET 210(2) have the same thin-gate insulator, and the third and sixth varactors 218(3), 418(3) and the third FET 210(3) have the same thin-gate insulator in this example, the input voltage V_{IN} will be divided evenly between the first FET 210(1) and the first and fourth varactors 218(1) 418(1), divided evenly between the second FET 210(2) and the second and fifth varactors 218(2), 418(2), and divided evenly between the third FET 210(3) and the third and sixth varactors 218(3), 418(3) for both an AC and DC input signal 204.

In this manner, the gate voltages V_{G1}, V_{G2}, V_{G3} can be provided within the breakdown voltages of the respective FETs 210(1)-210(3), but the FETs 210(1)-210(3) being series coupled to each other allows the output signals 208(1), 208(2) generated on the output nodes 206(1), 206(2) to be in the voltage domain and voltage range of the supply voltage V_{DD}. Thus, the electronic device 400 will have an effective overall breakdown voltage that is at least the supply voltage V_{DD} and greater than the breakdown voltage of the individual FETs 210(1)-210(3). In this manner, the electronic device 400 can be provided that has the single input node 202 without the requirement for voltage level shifting of the input signal 204 and without the need for additional FETs to apply offset voltages to the FETs 210(1)-210(3) like the electronic device 100 in FIG. 1.

Also note that the varactors 418(1)-418(3) can be provided as thin-gate insulator devices similar to the varactors 218(1)-218(3) and/or the FETs 210(1)-210(3) and also discussed with regard to FIG. 2A-1. This is because the division of the input voltage V_{IN} across the varactors 418(1)-418(3) reduces the voltage across the varactors 418(1)-418(3). Thus, the varactors 418(1)-418(3) can also be designed with thinner gate insulators 232 (see FIG. 2A-1) that provide for their having lower breakdown voltages than the supply voltage V_{DD}. Also note that by inclusion of the series connected varactor circuits 416(1)-416(3) between the input node 202 and the respective FETs 210(1)-210(2), the FETs 210(1)-210(3) are also electrically isolated from the input node 202. This may have the benefit of reducing leakage voltage of the FETs 210(1)-210(3) when the input signal 204 is inactive or does not have a sufficient input voltage V_{IN} that when divided, activates (exceeds the threshold voltage) the FETs 210(1)-210(3).

FIG. 4B is a circuit layout diagram of an electronic device 400(1) that has a circuit arrangement like the electronic device 400 in FIG. 4A and similar to the electronic device 300(1) in FIG. 3B. However, in the electronic device 400(1) in FIG. 4B, the varactors circuits 416(1)-416(3) include P+/P-well varactors 218P(1)-218P (3) and N+/N-well varactors 418N(1)-418N(3) each coupled in series to respective NFETs 210N(1)-210N(3) as the FETs 210(1)-210(3). Common elements between the electronic device 300(1) in FIG. 3B, the electronic device 400 in FIG. 4A and the electronic device 400(1) in FIG. 4B are shown with common element numbers.

In this regard, as shown in FIG. 4B, the electronic device 400(1) includes first and second circuits 440(1), 440(2). The second circuit 440(2) is included in the electronic device 400(1) to provide the additional varactors 418N(1)-418N(3) as part of the respective varactor circuits 416(1)-416(3). The first circuit 440(1) includes the varactors 218P(1)-218P (3) and the NFETs 210N(1)-210N(3) similar to the circuit 340(1) in the electronic device 300(1) in FIG. 3B. In this regard, with reference to FIG. 4B, the first circuit 440(1) includes a first diffusion region 442, which is a P+ implant diffusion region 442P (“P diffusion region 442P”) in this example, and a second diffusion region 444, which is an N+ implant diffusion region 444N (“N diffusion region 444N”) and opposite polarity of the P diffusion region 444P in this example. The first circuit 440(1) can be a cell circuit that is provided in a standard cell as a non-limiting example. The P and N diffusion regions 442P, 444N are disposed on a P-well substrate 446P (P-well 446P) in this example. The first, second, and third gate structures 348(1), 348(2), 348(3) both extend in the first and second diffusion regions 442P, 444N in a first direction (Y-axis direction) without gate cuts. In this manner, the gate structures 348(1)-348(3) provide a coupling between the respective cathodes 236P(1)-236P (3) of the respective varactors 218P(1)-218P (3) in the P diffusion region 442P, and the respective gates G₁, G₂, G₃ of the respective NFETs 210N(1)-210N(3).

Further, as shown in FIG. 4B, the second circuit 440(2) includes a third diffusion region 442N, which is a N+ implant diffusion region 442N (“N diffusion region 442N”) in this example of the polarity of the second diffusion region 444N. The second circuit 440(2) can be a cell circuit that is provided in a standard cell as a non-limiting example. The N diffusion region 442N is disposed on an N-well substrate 446N (N-well 446N) in this example. The varactors 418N(1)-418N(3) are each formed in the N diffusion region 442N as N+/N-well varactors. The varactors 418N(1)-418N(3) have respective first, second, and third anodes 434N(1)-434N(3) and first, second, and third cathodes 436N(1)-436N(3). The first, second, and third cathodes 436N(1)-436N(3) of the fourth, fifth, and sixth varactors 418N(1)-418N(3) are coupled to fourth, fifth, and sixth gate structures 448(1), 448(2), 448(3) which are then coupled to the anodes 234P(1), 234P(2), 234P (3) of the varactors 218P(1)-218P (3) through a metal line 450 in a metal layer 452 (e.g., MO layer). Further, as shown in FIG. 4B, the input node 202 in this example is formed by a second metal line 456 also in the first metal layer 452 that is coupled to first, second, and third contacts 454N(1), 454N(2), 454N(3) coupled to the respective anodes 434N(1)-434N(3) of the respective varactors 418N(1)-418N(3).

FIG. 4C is a circuit layout diagram of another electronic device 400(2) that has a circuit arrangement like the electronic device 400 in FIG. 4A and similar to the electronic device 300(2) in FIG. 3C. However, the electronic device 400(2) in FIG. 4C has the varactors circuits 416(1)-416(3) that include N+/N-well varactors 218N(1)-218N(3) and P+/P-well varactors 418P(1)-418P (3) each coupled in series to respective PFETs 210P(1)-210P (3) as the FETs 210(1)-210(3). Common elements between the electronic device 300(2) in FIG. 3C, the electronic device 400 in FIG. 4A and the electronic device 400(1) in FIG. 4B are shown with common element numbers.

In this regard, as shown in FIG. 4C, the electronic device 400(2) includes first and second circuits 440(3), 440(4). The second circuit 440(4) is included in the electronic device 400(2) to provide the additional varactors 418P(1)-418P (3) as part of the respective varactor circuits 416(1)-416(3). The first circuit 440(3) includes the varactors 218N(1)-218N(3) and the PFETs 210P(1)-210P (3) similar to the circuit 340(2) in the electronic device 300(2) in FIG. 3C. In this regard, with reference to FIG. 4C, the first circuit 440(3) includes a first diffusion region 442, which is an N+ implant diffusion region 442N (“P diffusion region 442N”) in this example, and a second diffusion region 444, which is a P+ implant diffusion region 444P (“P diffusion region 444P”) and opposite polarity of the N diffusion region 442N in this example. The N and P diffusion regions 442N, 444P are disposed on an N-well substrate 446N (N-well 446N) in this example. The first, second, and third gate structures 348(1), 348(2), 348(3) both extend in the first and second diffusion regions 442N, 444P in a first direction (Y-axis direction) without gate cuts. In this manner, the gate structures 348(1)-348(3) provide a coupling between the respective cathodes 236N(1)-236N(3) of the respective varactors 218N(1)-218N(3) in the N diffusion region 442N, and the respective gates G₁, G₂, G₃ of the respective PFETs 210P(1)-210P (3).

Further, as shown in FIG. 4C, the second circuit 440(2) includes a third diffusion region 442P, which is a P+ implant diffusion region 442P (“P diffusion region 442P”) in this example of the polarity of the second diffusion region 444P. The P diffusion region 442P is disposed on a P-well substrate 446P (P-well 446P) in this example. The varactors 418P(1)-418P (3) are each formed in the P diffusion region 442P as P+/P-well varactors. The varactors 418P(1)-418P (3) have respective first, second, and third anodes 434P(1)-434P (3) and first, second, and third cathodes 436P(1)-436P (3). The first, second, and third cathodes 436P(1)-436P (3) of the fourth, fifth, and sixth varactors 418P(1)-418P (3) are coupled to fifth, and sixth gate structures 448(1), 448(2), 448(3) which are then coupled to the anodes 234N(1), 234N(2), 234N(3) of the varactors 218N(1)-218N(3) through the metal line 450 in the metal layer 452 (e.g., MO layer). Further, as shown in FIG. 4C, the input node 202 in this example is formed by the second metal line 456 also in the first metal layer 452 that is coupled to first, second, and third contacts 454P(1), 454P(2), 454P (3) coupled to the respective anodes 434P(1)-434P (3) of the respective varactors 418P(1)-418P (3).

There are various manners in which an electronic device that includes a plurality of varactors each coupled in series to a respective gate of a thin-gate insulator transistor, to provide a voltage divider of an input signal between each varactor and its respective series coupled gate of a thin-gate insulator transistor to support a higher supply voltage than the breakdown voltages of the thin-gate insulator transistors, including, but not limited to, the electronic devices 200, 200(1), 200(2), 300, 300(1), 300(2), 400, 400(1), 400(2) in FIGS. 2A-1-4C.

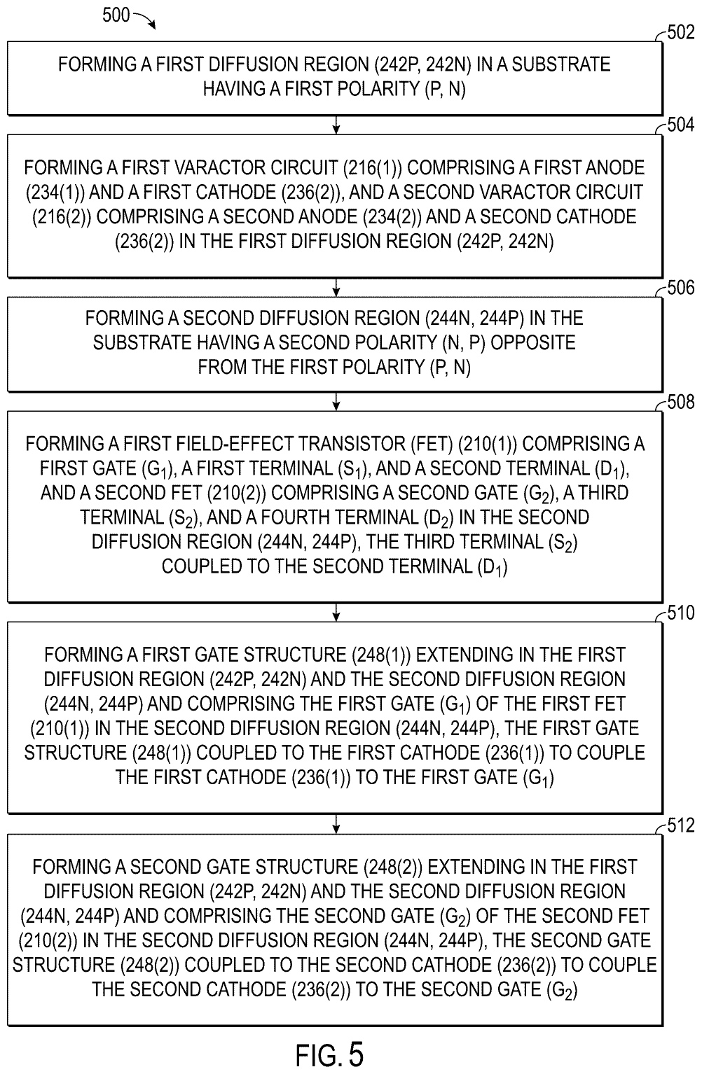

In this regard, FIG. 5 is a flowchart illustrating an exemplary fabrication process 500 of fabricating an electronic device that includes a plurality of varactors each coupled in series to a respective gate of a thin-gate insulator transistor, to provide a voltage divider of an input signal between each varactor and its respective series coupled gate of a thin-gate insulator transistor to support a higher supply voltage than the breakdown voltages of the thin-gate insulator transistors. The exemplary fabrication process 500 in FIG. 5 is discussed with regard to the example electronic devices 200, 200(1), 200(2) in FIGS. 2A-1-2A-2, 2B, and 2C. However, note that the fabrication process 500 in FIG. 5 could be employed to fabricate any electronic device that includes a plurality of varactors each coupled in series to a respective gate of a thin-gate insulator transistor, to provide a voltage divider of an input signal between each varactor and its respective series coupled gate of a thin-gate insulator transistor to support a higher supply voltage than the breakdown voltages of the thin-gate insulator transistors, including, but not limited to, the other electronic devices 300, 300(1), 300(2), 400, 400(1), 400(2) in FIGS. 3A-4C.

As shown in FIG. 5, a first step to fabricate the electronic devices 200, 200(1), 200(2) can be forming a first diffusion region 242P, 242N in a substrate having a first polarity P, N (block 502 in FIG. 5). A next step to fabricate the electronic devices 200, 200(1), 200(2) can be forming a first varactor circuit 216(1) comprising a first anode 234(1) and a first cathode 236(2), and a second varactor circuit 216(2) comprising a second anode 234(2) and a second cathode 236(2) in the first diffusion region 242P, 242N (block 504 in FIG. 5). A next step to fabricate the electronic devices 200, 200(1), 200(2) can be forming a second diffusion region 244N, 244P in the substrate having a second polarity N, P opposite from the first polarity P, N (block 506 in FIG. 5). A next step to fabricate the electronic devices 200, 200(1), 200(2) can be forming a first FET 210(1) comprising a first gate G₁, a first terminal S₁, and a second terminal D₁, and a second FET 210(2) comprising a second gate G₂, a third terminal S₂, and a fourth terminal D₂ in the second diffusion region 244N, 244P, the third terminal S₂ coupled to the second terminal D₁ (block 508 in FIG. 5). A next step to fabricate the electronic devices 200, 200(1), 200(2) can be forming a first gate structure 248(1) extending in the first diffusion region 242P, 242N and the second diffusion region 244N, 244P and comprising the first gate G₁ of the first FET 210(1) in the second diffusion region 244N, 244P, the first gate structure 248(1) coupled to the first cathode 236(1) to couple the first cathode 236(1) to the first gate G₁ (block 510 in FIG. 5). A next step to fabricate the electronic devices 200, 200(1), 200(2) can be forming a second gate structure 248(2) extending in the first diffusion region 242P, 242N and the second diffusion region 244N, 244P and comprising the second gate G₂ of the second FET 210(2) in the second diffusion region 244N, 244P, the second gate structure 248(2) coupled to the second cathode 236(2) to couple the second cathode 236(2) to the second gate G₂ (block 512 in FIG. 5).

Also note that the terms “top” and “bottom” where used herein are relative terms and are not meant to limit or imply a strict orientation that an element referenced as being “above” another referenced element must always be oriented to be above the other referenced element with respect to ground, or that an element referenced as being “below” another referenced element must always be oriented to be below the other referenced element with respect to ground.

Also note that the transistors disclosed herein can be FETs or could be any other type of transistor, and could include planar, FinFET and/or GAA transistors or FETS. The thin-gate insulator transistors and thin-gate varactors disclosed herein could have any type of gate insulators that are gate oxide or any other type of insulator and/or dielectric material desired. The electronic devices could include any number of transistors coupled together in series desired, and any number of varactors (coupled in series or not) to each other as a varactor circuit coupled to respective transistors.

An electronic device that includes a plurality of varactors each coupled in series to a respective gate of a thin-gate insulator transistor, to provide a voltage divider of an input signal between each varactor and its respective series coupled gate of a thin-gate insulator transistor to support a higher supply voltage than the breakdown voltages of the thin-gate insulator transistors, including, but not limited, to the exemplary electronic devices 200, 200(1), 200(2), 300, 300(1), 300(2), 400, 400(1), 400(2) in FIGS. 2A-1-4C, and according to any fabrication processes, including, but not limited to, the exemplary fabrication process 500 in FIG. 5, and according to any other aspect disclosed herein, may be provided in or integrated into any processor-based device. Examples, without limitation, include a set top box, an entertainment unit, a navigation device, a communications device, a fixed location data unit, a mobile location data unit, a global positioning system (GPS) device, a mobile phone, a cellular phone, a smart phone, a session initiation protocol (SIP) phone, a tablet, a phablet, a server, a computer, a portable computer, a mobile computing device, a wearable computing device (e.g., a smart watch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, avionics systems, a drone, and a multicopter.

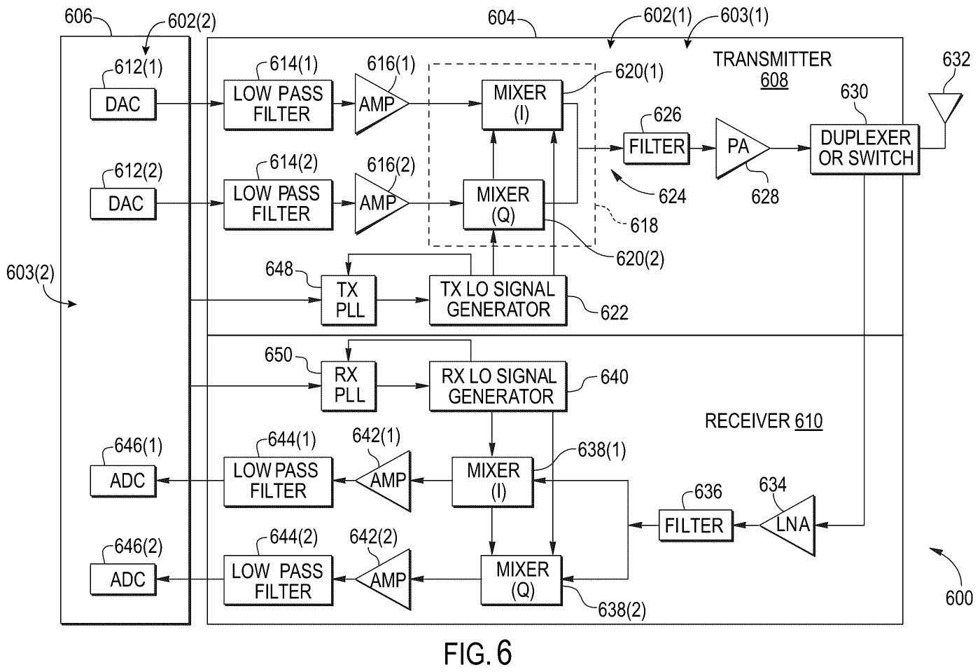

In this regard, FIG. 6 illustrates an exemplary wireless communications device 600 that includes radio frequency (RF) components formed from one or more ICs 602(1), 602(2), wherein any of the ICs 602(1), 602(2) can include an electronic device 603(1), 603(2) that includes a plurality of varactors each coupled in series to a respective gate of a thin-gate insulator transistor, to provide a voltage divider of an input signal between each varactor and its respective series coupled gate of a thin-gate insulator transistor to support a higher supply voltage than the breakdown voltages of the thin-gate insulator transistors, including, but not limited, to the exemplary electronic devices 200, 200(1), 200(2), 300, 300(1), 300(2), 400, 400(1), 400(2) in FIGS. 2A-1-4C, and according to any fabrication processes, including, but not limited to, the exemplary fabrication process 500 in FIG. 5, and according to any other aspect disclosed herein. The wireless communications device 600 may include or be provided in any of the above-referenced devices, as examples. As shown in FIG. 6, the wireless communications device 600 includes a transceiver 604 and a data processor 606. The transceiver 604 can include one or more of the electronic device 603(1). The data processor 606 can include one or more of the electronic device 603(2). The data processor 606 may include a memory to store data and program codes. The transceiver 604 includes a transmitter 608 and a receiver 610 that support bi-directional communications. In general, the wireless communications device 600 may include any number of transmitters 608 and/or receivers 610 for any number of communication systems and frequency bands. All or a portion of the transceiver 604 may be implemented on one or more analog ICs, RFICs, mixed-signal ICs, etc.

The transmitter 608 or the receiver 610 may be implemented with a super-heterodyne architecture or a direct-conversion architecture. In the super-heterodyne architecture, a signal is frequency-converted between RF and baseband in multiple stages, e.g., from RF to an intermediate frequency (IF) in one stage, and then from IF to baseband in another stage for the receiver 610. In the direct-conversion architecture, a signal is frequency-converted between RF and baseband in one stage. The super-heterodyne and direct-conversion architectures may use different circuit blocks and/or have different requirements. In the wireless communications device 600 in FIG. 6, the transmitter 608 and the receiver 610 are implemented with the direct-conversion architecture.

In the transmit path, the data processor 606 processes data to be transmitted and provides I and Q analog output signals to the transmitter 608. In the exemplary wireless communications device 600, the data processor 606 includes digital-to-analog converters (DACs) 612(1), 612(2) for converting digital signals generated by the data processor 606 into the I and Q analog output signals, e.g., I and Q output currents, for further processing.

Within the transmitter 608, lowpass filters 614(1), 614(2) filter the I and Q analog output signals, respectively, to remove undesired signals caused by the prior digital-to-analog conversion. Amplifiers (AMPs) 616(1), 616(2) amplify the signals from the lowpass filters 614(1), 614(2), respectively, and provide I and Q baseband signals. An upconverter 618 upconverts the I and Q baseband signals with I and Q transmit (TX) local oscillator (LO) signals through mixers 620(1), 620(2) from a TX LO signal generator 622 to provide an upconverted signal 624. A filter 626 filters the upconverted signal 624 to remove undesired signals caused by the frequency upconversion as well as noise in a receive frequency band. A power amplifier (PA) 628 amplifies the upconverted signal 624 from the filter 626 to obtain the desired output power level and provides a transmit RF signal. The transmit RF signal is routed through a duplexer or switch 630 and transmitted via an antenna 632.

In the receive path, the antenna 632 receives signals transmitted by base stations and provides a received RF signal, which is routed through the duplexer or switch 630 and provided to a low noise amplifier (LNA) 634. The duplexer or switch 630 is designed to operate with a specific receive (RX)-to-TX duplexer frequency separation, such that RX signals are isolated from TX signals. The received RF signal is amplified by the LNA 634 and filtered by a filter 636 to obtain a desired RF input signal. Downconversion mixers 638(1), 638(2) mix the output of the filter 636 with I and Q RX LO signals (i.e., LO_I and LO_Q) from an RX LO signal generator 640 to generate I and Q baseband signals. The I and Q baseband signals are amplified by AMPs 642(1), 642(2) and further filtered by lowpass filters 644(1), 644(2) to obtain I and Q analog input signals, which are provided to the data processor 606. In this example, the data processor 606 includes analog-to-digital converters (ADCs) 646(1), 646(2) for converting the analog input signals into digital signals to be further processed by the data processor 606.

In the wireless communications device 600 of FIG. 6, the TX LO signal generator 622 generates the I and Q TX LO signals used for frequency upconversion, while the RX LO signal generator 640 generates the I and Q RX LO signals used for frequency downconversion. Each LO signal is a periodic signal with a particular fundamental frequency. A TX phase-locked loop (PLL) circuit 648 receives timing information from the data processor 606 and generates a control signal used to adjust the frequency and/or phase of the TX LO signals from the TX LO signal generator 622. Similarly, an RX PLL circuit 650 receives timing information from the data processor 606 and generates a control signal used to adjust the frequency and/or phase of the RX LO signals from the RX LO signal generator 640.

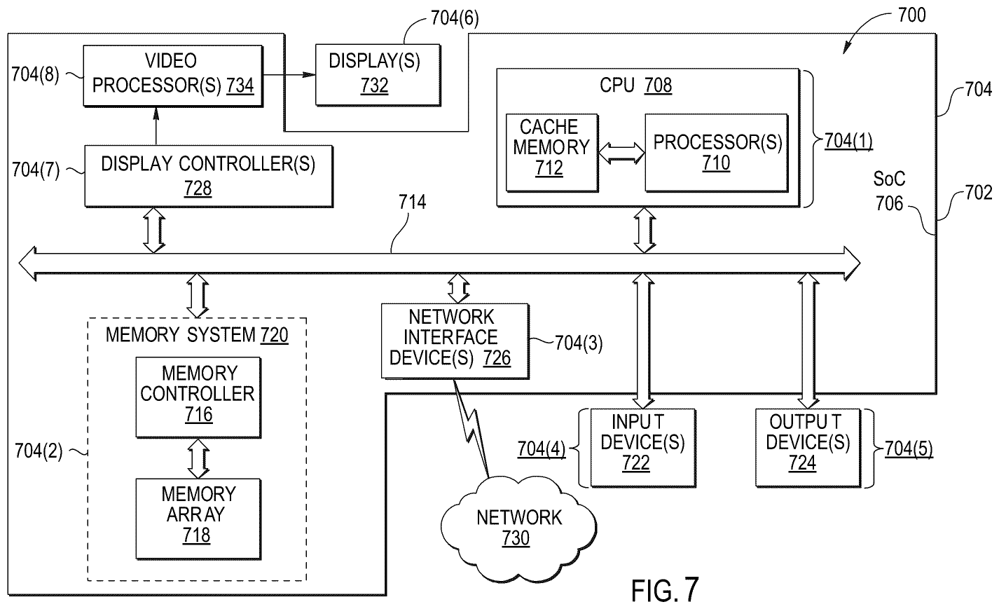

FIG. 7 illustrates an example of a processor-based system 700. The components of the processor-based system 700 are ICs 702. Some or all of the components in the processor-based system 700 can include can include an electronic device 704, 704(1)-704(8) that includes a plurality of varactors each coupled in series to a respective gate of a thin-gate insulator transistor, to provide a voltage divider of an input signal between each varactor and its respective series coupled gate of a thin-gate insulator transistor to support a higher supply voltage than the breakdown voltages of the thin-gate insulator transistors, including, but not limited, to the exemplary electronic devices 200, 200(1), 200(2), 300, 300(1), 300(2), 400, 400(1), 400(2) in FIGS. 2A-1-4C, and according to any fabrication processes, including, but not limited to, the exemplary fabrication process 500 in FIG. 5, and according to any other aspect disclosed herein.

In this example, the processor-based system 700 may include electronic devices 704 as a system-on-a-chip (SoC) 706. The processor-based system 700 includes a CPU 708 that includes one or more processors 710, which may also be referred to as CPU cores or processor cores. The CPU 708 can include electronic devices 704(1). The CPU 708 may have cache memory 712 coupled to the CPU 708 for rapid access to temporarily stored data. The CPU 708 is coupled to a system bus 714 and can intercouple master and slave devices included in the processor-based system 700. As is well known, the CPU 708 communicates with these other devices by exchanging address, control, and data information over the system bus 714. For example, the CPU 708 can communicate bus transaction requests to a memory controller 716 as an example of a slave device. Although not illustrated in FIG. 7, multiple system buses 714 could be provided, wherein each system bus 714 constitutes a different fabric.

Other master and slave devices can be connected to the system bus 714. As illustrated in FIG. 7, these devices can include a memory system 720 that includes the memory controller 716 and a memory array(s) 718, one or more input devices 722, one or more output devices 724, one or more network interface devices 726, and one or more display controllers 728, as examples. The memory system 720 can include electronic devices 704(2). The network interface devices 726 can include electronic devices 704(3). Each of the memory system 720, the one or more input devices 722, the one or more output devices 724, the one or more network interface devices 726, and the one or more display controllers 728 can be provided in the same or different circuit packages. The input devices 722 and/or the output devices 724 can include electronic devices 704(5), 704(5). The input device(s) 722 can include any type of input device, including, but not limited to, input keys, switches, voice processors, etc. The output device(s) 724 can include any type of output device, including, but not limited to, audio, video, other visual indicators, etc. The network interface device(s) 726 can be any device configured to allow exchange of data to and from a network 730. The network 730 can be any type of network, including, but not limited to, a wired or wireless network, a private or public network, a local area network (LAN), a wireless local area network (WLAN), a wide area network (WAN), a BLUETOOTH™ network, and the Internet. The network interface device(s) 726 can be configured to support any type of communications protocol desired.

The CPU 708 may also be configured to access the display controller(s) 728 over the system bus 714 to control information sent to one or more displays 732. The display 732 can include electronic devices 704(6). The display controller(s) 728 sends information to the display(s) 732 to be displayed via one or more video processors 734, which process the information to be displayed into a format suitable for the display(s) 732. The display controller(s) 728 and video processor(s) 734 can include electronic devices 704(7), 704(8) and the same or different circuit packages, and in the same or different circuit packages containing the CPU 708 as an example. The display(s) 732 can include any type of display, including, but not limited to, a cathode ray tube (CRT), a liquid crystal display (LCD), a plasma display, a light emitting diode (LED) display, etc.

Those of skill in the art will further appreciate that the various illustrative logical blocks, modules, circuits, and algorithms described in connection with the aspects disclosed herein may be implemented as electronic hardware, instructions stored in memory or in another computer readable medium and executed by a processor or other processing device, or combinations of both. The master and slave devices described herein may be employed in any circuit, hardware component, IC, or IC chip, as examples. Memory disclosed herein may be any type and size of memory and may be configured to store any type of information desired. To clearly illustrate this interchangeability, various illustrative components, blocks, modules, circuits, and steps have been described above generally in terms of their functionality. How such functionality is implemented depends upon the particular application, design choices, and/or design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A processor may be a microprocessor, but in the alternative, the processor may be any conventional processor, controller, microcontroller, or state machine. A processor may also be implemented as a combination of computing devices (e.g., a combination of a DSP and a microprocessor, a plurality of microprocessors, one or more microprocessors in conjunction with a DSP core, or any other such configuration).

The aspects disclosed herein may be embodied in hardware and in instructions that are stored in hardware, and may reside, for example, in Random Access Memory (RAM), flash memory, Read Only Memory (ROM), Electrically Programmable ROM (EPROM), Electrically Erasable Programmable ROM (EEPROM), registers, a hard disk, a removable disk, a CD-ROM, or any other form of computer readable medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a remote station. In the alternative, the processor and the storage medium may reside as discrete components in a remote station, base station, or server.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations. Thus, the disclosure is not intended to be limited to the examples and designs described herein, but is to be accorded the widest scope consistent with the principles and novel features disclosed herein.

Implementation examples are described in the following numbered clauses:
1. An electronic device, comprising:
   a first field-effect transistor (FET) comprising a first gate, a first terminal, and a second terminal;
   a second FET comprising a second gate, a third terminal, and a fourth terminal, the third terminal coupled in series to the second terminal;
   a first varactor circuit comprising a first anode and a first cathode, the first cathode coupled to the first gate;
   a second varactor circuit comprising a second anode and a second cathode, the second cathode coupled to the second gate;
   an input node comprising the first anode coupled to the second anode; and
   an output node coupled to at least one of the second terminal and the third terminal.
2. The electronic device of clause 1, wherein:
   the first FET has a first breakdown voltage between the first gate and the first terminal;
   the second FET has a second breakdown voltage between the second gate and the fourth terminal; and
   the electronic device has an overall breakdown voltage between the first terminal and the fourth terminal greater than the first breakdown voltage and the second breakdown voltage.
3. The electronic device of clause 1 or 2, configured to generate an output signal on the output node in a voltage domain of a supply voltage applied across the first terminal and the fourth terminal, based on an input signal on the input node.
4. The electronic device of any of clauses 1-3, wherein the first varactor circuit comprises a first varactor, and the second varactor circuit comprises a second varactor.
5. The electronic device of any of clauses 1-4, wherein:
   the first FET further comprises a first channel and a first insulator between the first gate and the first channel, the first insulator having a first thickness in a first direction from the first gate to the first channel equal to or less than two (2) nanometers (nm); and
   the second FET further comprises a second channel and a second insulator between the second gate and the second channel, the second insulator having a second thickness in a second direction from the second gate to the second channel equal to or less than two (2) nm.
6. The electronic device of clause 5, wherein:
   the first varactor circuit comprises a third gate between the first anode and the first cathode, and a third insulator between the third gate and the first cathode, the third insulator having a third thickness equal to the first thickness in a third direction from the third gate to the first cathode; and
   the second varactor circuit comprises a fourth gate between the second anode and the second cathode, and a fourth insulator between the fourth gate and the second cathode, the fourth insulator having a fourth thickness equal to the second thickness in a fourth direction from the fourth gate.
7. The electronic device of clause 5 or 6, wherein:
   the first FET further comprises a first gate oxide between the first gate and the first channel; and
   the second FET further comprises a second gate oxide between the second gate and the second channel.
8. The electronic device of any of clauses 1-7, wherein the first terminal comprises a first source of the first FET, and the fourth terminal comprises a second drain of the second FET.
9. The electronic device of any of clauses 1-8, wherein the first FET comprises a first gate-all-around (GAA) FET, and the second FET comprises a second GAA FET.
10. The electronic device of any of clauses 1-8, wherein the first FET comprises a first FinFET, and the second FET comprises a second FinFET.
11. The electronic device of any of clauses 1-10, wherein:
   the first terminal comprises a first source of the first FET;
   the fourth terminal comprises a second drain of the second FET;
   the second terminal comprises a first drain of the first FET; and
   the third terminal comprises a second source of the second FET coupled to the first drain of the first FET.
12. The electronic device of any of clauses 1-10, further comprising:
   a third FET comprising a third gate, a fifth terminal, and a sixth terminal,
      the third FET having a third breakdown voltage between the third gate and the fifth terminal; and
   a third varactor circuit comprising a third anode and a third cathode, the third cathode coupled to the third gate;
   wherein:
      the input node further comprises the third anode coupled to the first anode and the second anode; and
      the output node is further coupled to one of the second terminal coupled to the fifth terminal, and the third terminal coupled to the sixth terminal;
   the electronic device having the overall breakdown voltage between the first terminal and the fourth terminal greater than the first breakdown voltage, the second breakdown voltage, and the third breakdown voltage.
13. The electronic device of clause 12, wherein:
   the first terminal comprises a first source of the first FET;
   the second terminal comprises a first drain of the first FET;
   the third terminal comprises a second source of the second FET;
   the fourth terminal comprises a second drain of the second FET;
   the fifth terminal comprises a third source of the third FET;
   the sixth terminal comprises a third drain of the third FET;
   the first drain of the first FET is coupled to the third source of the third FET; and
   the second source of the second FET is coupled to the third drain of the third FET.
14. The electronic device of any of clauses 1-10, wherein:
   the first varactor circuit comprises:
      a first varactor comprising a third anode and the first cathode; and
      a third varactor comprising the first anode and a third cathode;
   the second varactor circuit comprises:
      a second varactor comprising a fourth anode and the second cathode; and
      a fourth varactor comprising the second anode and a fourth cathode; and
   the electronic device further comprises a second input node comprising the third cathode coupled to the third anode, and the fourth cathode coupled to the fourth anode.
15. The electronic device of clause 14, wherein:
   the first FET further comprises a first channel and a first insulator between the first gate and the first channel, the first insulator having a first thickness in a first direction from the first gate to the first channel equal to or less than two (2) nanometers (nm); and
   the second FET further comprises a second channel and a second insulator between the second gate and the second channel, the second insulator having a second thickness in a second direction from the second gate to the second channel equal to or less than two (2) nm.
16. The electronic device of clause 15, wherein:
   the first varactor comprises a third gate between the third anode and the first cathode, and a third insulator between the third gate and the first cathode, the third insulator having a third thickness equal to the first thickness in a third direction from the third gate to the first cathode;
   the second varactor comprises a fourth gate between the fourth anode and the second cathode, and a fourth insulator between the fourth gate and the second cathode, the fourth insulator having a fourth thickness equal to the first thickness in a fourth direction from the fourth gate to the second cathode equal;
   the third varactor comprises a fifth gate between the first anode and the third cathode, and a fifth insulator between the fifth gate and the third cathode, the fifth insulator having a fifth thickness equal to the first thickness in a fifth direction from the fifth gate to the third cathode; and
   the fourth varactor comprises a sixth gate between the second anode and the fourth cathode, and a sixth insulator between the sixth gate and the fourth cathode, the sixth insulator having a sixth thickness equal to the first thickness in a sixth direction from the sixth gate to the fourth cathode.
17. The electronic device of clause 16, wherein:
   the first varactor comprises a third gate between the third anode and the first cathode, and a third insulator between the third gate and the first cathode, the third insulator having a third thickness equal to the first thickness in a third direction from the third gate to the first cathode;
   the second varactor comprises a fourth gate between the fourth anode and the second cathode, and a fourth insulator between the fourth gate and the second cathode, the fourth insulator having a fourth thickness equal to the first thickness in a fourth direction from the fourth gate to the second cathode;
   the third varactor comprises a fifth gate between the first anode and the third cathode, and a fifth insulator between the fifth gate and the third cathode, the fifth insulator having a fifth thickness equal to the first thickness in a fifth direction from the fifth gate to the third cathode; and
   the fourth varactor comprises a sixth gate between the second anode and the fourth cathode, and a sixth insulator between the sixth gate and the fourth cathode, the sixth insulator having a sixth thickness equal to the first thickness in a sixth direction from the sixth gate to the fourth cathode.
18. The electronic device of any of clauses 1-17 integrated into a device selected from the group consisting of: a set top box; an entertainment unit; a navigation device; a communications device; a fixed location data unit; a mobile location data unit; a global positioning system (GPS) device; a mobile phone; a cellular phone; a smart phone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; an avionics system; a drone; and a multicopter.
19. An electronic device comprising:
   a first circuit, comprising:
      a first diffusion region in a substrate having a first polarity;
      a first varactor circuit comprising a first anode and a first cathode formed in the first diffusion region;
      a second varactor circuit comprising a second anode and a second cathode formed in the first diffusion region;
      a second diffusion region in the substrate having a second polarity opposite from the first polarity;
      a first field-effect transistor (FET) comprising a first gate, a first terminal, and a second terminal in the second diffusion region;
      a second FET comprising a second gate, a third terminal, and a fourth terminal in the second diffusion region, the third terminal coupled in series to the second terminal;
      a first gate structure extending in the first diffusion region and the second diffusion region and comprising the first gate of the first FET in the second diffusion region, the first gate structure coupled to the first cathode to couple the first cathode to the first gate; and
      a second gate structure extending in the first diffusion region and the second diffusion region and comprising the second gate of the second FET in the second diffusion region, the second gate structure coupled to the second cathode to couple the second cathode to the second gate; and
   an input node coupled to the first anode and the second anode; and
   an output node coupled to at least one of the second terminal and the third terminal.
20. The electronic device of clause 19, wherein:
   the first FET has a first breakdown voltage between the first gate and the first terminal;
   the second FET has a second breakdown voltage between the second gate and the fourth terminal; and
   the electronic device has an overall breakdown voltage between the first terminal and the fourth terminal greater than the first breakdown voltage and the second breakdown voltage.
21. The electronic device of clause 19 or 20, further comprising:
   a first contact coupled to the first anode; and
   a second contact coupled to the second anode;
   wherein:
      the input node comprises a first metal line in a first metal layer coupled to the first contact coupled to the first anode and the second contact coupled to the second anode.
22. The electronic device of any of clauses 19-21, wherein:
   the first circuit further comprises a P-type semiconductor (P)-well;
   the first diffusion region comprises a P implant in the P-well;
   the second diffusion region comprises an N-type semiconductor (N) implant in the P-well;
   the first FET comprises a first NFET, wherein:
      the first terminal comprises a first N terminal; and
      the second terminal comprises a second N terminal; and
   the second FET comprises a second NFET, wherein:
      the third terminal comprises a third N terminal; and
      the fourth terminal comprises a fourth N terminal.
23 The electronic device of any of clauses 19-21, wherein:
   the first circuit further comprises an N-type semiconductor (N)-well;
   the first diffusion region comprises an N implant in the N-well;
   the second diffusion region comprises a P-type semiconductor (P) implant in the N-well;
   the first FET comprises a first PFET, wherein:
      the first terminal comprises a first P terminal; and
      the second terminal comprises a second P terminal; and
   the second FET comprises a second PFET, wherein:
      the third terminal comprises a third P terminal; and
      the fourth terminal comprises a fourth P terminal.
24. The electronic device of clauses 19-21, wherein the first circuit further comprises:
   a third varactor circuit comprising a third anode and a third cathode in the first diffusion region;
   a third FET comprising a third gate, a fifth terminal, and a sixth terminal in the second diffusion region; and
   a third gate structure extending in the first diffusion region and the second diffusion region and comprising the third gate in the second diffusion region, the third gate structure coupled to the third cathode to couple the third cathode to the third gate;
   wherein:
      the input node further comprises the third anode coupled to the first anode and the second anode; and
      the output node is further coupled to one of the second terminal coupled to the fifth terminal, and the third terminal coupled to the sixth terminal.
25. The electronic device of clause 24, further comprising:
   a first contact coupled to the first anode;
   a second contact coupled to the second anode; and
   a third contact coupled to the third anode;
   wherein:
      the input node comprises a first metal line in a first metal layer coupled to the first contact coupled to the first anode, coupled to the second contact coupled to the second anode; and coupled to the third contact coupled to the third anode.
26 The electronic device of clause 24 or 25, wherein:
   the first circuit further comprises a P-type semiconductor (P)-well;
   the first diffusion region comprises a P implant in the P-well;
   the second diffusion region comprises an N-type semiconductor (N) implant in the P-well;
   the first FET comprises a first NFET, wherein:
      the first terminal comprises a first N terminal; and
      the second terminal comprises a second N terminal;
   the second FET comprises a second NFET, wherein:
      the third terminal comprises a third N terminal; and
      the fourth terminal comprises a fourth N terminal; and
   the third FET comprises a third NFET, wherein:
      the fifth terminal comprises a fifth N terminal; and
      the sixth terminal comprises a sixth N terminal.
27 The electronic device of clause 24 or 25, wherein:
   the first circuit further comprises an N-type semiconductor (N)-well;
   the first diffusion region comprises an N implant in the N-well;
   the second diffusion region comprises a P-type semiconductor (P) implant in the N-well;
   the first FET comprises a first PFET, wherein:
      the first terminal comprises a first P terminal; and
      the second terminal comprises a second P terminal;
   the second FET comprises a second PFET, wherein:
      the third terminal comprises a third P terminal; and
      the fourth terminal comprises a fourth P terminal; and
   the third FET comprises a third PFET, wherein:
      the fifth terminal comprises a fifth P terminal; and
      the sixth terminal comprises a sixth P terminal.
28. The electronic device of any of clauses 24-27, wherein:
   the first terminal comprises a first source of the first FET;
   the second terminal comprises a first drain of the first FET;
   the third terminal comprises a second source of the second FET;
   the fourth terminal comprises a second drain of the second FET;
   the fifth terminal comprises a third source of the third FET;
   the sixth terminal comprises a third drain of the third FET;
   the first drain of the first FET is coupled to the third source of the third FET; and
   the second source of the second FET is coupled to the third drain of the third FET.
29 The electronic device of any of clauses 19-21, wherein:
   the first varactor circuit comprises:
      a first varactor comprising a third anode and the first cathode formed in the first diffusion region; and
      a third varactor comprising the first anode and a third cathode;
   the second varactor circuit comprises:
      a second varactor comprising a fourth anode and the second cathode formed in the first diffusion region; and
      a fourth varactor comprising the second anode and a fourth cathode; and
   further comprising:
      a first contact coupled to the third anode; and
      a second contact coupled to the fourth anode;
      a second circuit, comprising:
         a third diffusion region having the second polarity,
         the third varactor and the fourth varactor formed in the third diffusion region;
      a third contact coupled to the third cathode; and
      a fourth contact coupled to the fourth cathode;
   wherein:
      the input node comprises a first metal line in a first metal layer coupled to first contact, the second contact, the third contact, and the fourth contact; and
      the second circuit further comprises:
         a third gate structure in the third diffusion region, the third gate structure coupled to the first anode; and
         a fourth gate structure in the third diffusion region, the fourth gate structure coupled to the second anode; and
   further comprising:
      a second input node comprising a second metal line in a second metal layer coupled to the third gate structure and the fourth gate structure to couple the second input node to the first anode and the second anode.
30. The electronic device of clause 29, wherein the first metal layer comprises the second metal layer.
31. The electronic device of clause 29 or 30, wherein:
   the first circuit further comprises a P-type semiconductor (P)-well;
   the first diffusion region comprises a P implant in the P-well;
   the second diffusion region comprises an N-type semiconductor (N) implant in the P-well;
   the first FET comprises a first NFET, wherein:
      the first terminal comprises a first N terminal; and
      the second terminal comprises a second N terminal; and
   the second FET comprises a second NFET, wherein:
      the third terminal comprises a third N terminal; and
      the fourth terminal comprises a fourth N terminal;
   the second circuit further comprises an N well (N-well); and
   the third diffusion region comprises an N implant in the N-well.
32. The electronic device of clause 29 or 30, wherein:
   the first circuit further comprises an N-type semiconductor (N)-well;
   the first diffusion region comprises a N implant in the N-well;
   the second diffusion region comprises P-type semiconductor (P) implant in the N-well;
   the first FET comprises a first PFET, wherein:
      the first terminal comprises a first P terminal; and
      the second terminal comprises a second P terminal; and
   the second FET comprises a second PFET, wherein:
      the third terminal comprises a third P terminal; and
      the fourth terminal comprises a fourth P terminal;
   the second circuit further comprises a P well (P-well); and
   the third diffusion region comprises a P implant in the P-well.
33. The electronic device of any of clauses 19-32 integrated into a device selected from the group consisting of: a set top box; an entertainment unit; a navigation device; a communications device; a fixed location data unit; a mobile location data unit; a global positioning system (GPS) device; a mobile phone; a cellular phone; a smart phone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; an avionics system; a drone; and a multicopter.
34. A method of fabricating an electronic device, comprising:
   forming a first diffusion region in a substrate having a first polarity;
   forming a first varactor circuit comprising a first anode and a first cathode, and a second varactor circuit comprising a second anode and a second cathode in the first diffusion region;
   forming a second diffusion region in the substrate having a second polarity opposite from the first polarity;
   forming a first field-effect transistor (FET) comprising a first gate, a first terminal, and a second terminal, and a second FET comprising a second gate, a third terminal, and a fourth terminal in the second diffusion region, the third terminal coupled in series to the second terminal;
   forming a first gate structure extending in the first diffusion region and the second diffusion region and comprising the first gate of the first FET in the second diffusion region, the first gate structure coupled to the first cathode to couple the first cathode to the first gate; and
   forming a second gate structure extending in the first diffusion region and the second diffusion region and comprising the second gate of the second FET in the second diffusion region, the second gate structure coupled to the second cathode to couple the second cathode to the second gate.
35 The method of clause 34, further comprising:
   forming a third varactor circuit comprising a third anode and a third cathode in the first diffusion region;
   forming a third FET comprising a third gate, a fifth terminal, and a sixth terminal in the second diffusion region; and
   forming a third gate structure extending in the first diffusion region and the second diffusion region and comprising the third gate in the second diffusion region, the third gate structure coupled to the third cathode to couple the third cathode to the third gate.
36. The method of clause 34, further comprising:
   forming a third diffusion region in the substrate having the second polarity;
   wherein:
      forming the first varactor circuit comprises:
         forming a first varactor comprising a third anode and the first cathode formed in the first diffusion region; and
         forming a third varactor comprising the first anode and a third cathode formed in the third diffusion region;
      forming the second varactor circuit comprises:
         forming a second varactor comprising a fourth anode and the second cathode formed in the first diffusion region; and
         forming a fourth varactor comprising the second anode and a fourth cathode formed in the third diffusion region; and
   further comprising:
      forming a first contact coupled to the third anode; and
      forming a second contact coupled to the fourth anode;
      forming a third contact coupled to the third cathode; and
      forming a fourth contact coupled to the fourth cathode;
      forming a third gate structure in the third diffusion region, the third gate structure coupled to the first anode; and
      forming a fourth gate structure in the third diffusion region, the fourth gate structure coupled to the second anode.

What is claimed is:

1. An electronic device, comprising:
a first field-effect transistor (FET) comprising a first gate, a first terminal, and a second terminal;
a second FET comprising a second gate, a third terminal, and a fourth terminal, the third terminal coupled in series to the second terminal;
a first varactor circuit comprising a first anode and a first cathode, the first cathode coupled to the first gate;
a second varactor circuit comprising a second anode and a second cathode, the second cathode coupled to the second gate;
an input node comprising the first anode coupled to the second anode; and
an output node coupled to at least one of the second terminal and the third terminal.

2. The electronic device of claim 1, wherein:
the first FET has a first breakdown voltage between the first gate and the first terminal;
the second FET has a second breakdown voltage between the second gate and the fourth terminal; and
the electronic device has an overall breakdown voltage between the first terminal and the fourth terminal greater than the first breakdown voltage and the second breakdown voltage.

3. The electronic device of claim 1, configured to generate an output signal on the output node in a voltage domain of a supply voltage applied across the first terminal and the fourth terminal, based on an input signal on the input node.

4. The electronic device of claim 1, wherein the first varactor circuit comprises a first varactor, and the second varactor circuit comprises a second varactor.

5. The electronic device of claim 1, wherein:
the first FET further comprises a first channel and a first insulator between the first gate and the first channel, the first insulator having a first thickness in a first direction from the first gate to the first channel equal to or less than two (2) nanometers (nm); and
the second FET further comprises a second channel and a second insulator between the second gate and the second channel, the second insulator having a second thickness in a second direction from the second gate to the second channel equal to or less than two (2) nm.

6. The electronic device of claim 5, wherein:
the first varactor circuit comprises a third gate between the first anode and the first cathode, and a third insulator between the third gate and the first cathode, the third insulator having a third thickness equal to the first thickness in a third direction from the third gate to the first cathode; and
the second varactor circuit comprises a fourth gate between the second anode and the second cathode, and a fourth insulator between the fourth gate and the second cathode, the fourth insulator having a fourth thickness equal to the second thickness in a fourth direction from the fourth gate.

7. The electronic device of claim 5, wherein:
the first FET further comprises a first gate oxide between the first gate and the first channel; and
the second FET further comprises a second gate oxide between the second gate and the second channel.

8. The electronic device of claim 1, wherein the first terminal comprises a first source of the first FET, and the fourth terminal comprises a second drain of the second FET.

9. The electronic device of claim 1, wherein the first FET comprises a first gate-all-around (GAA) FET, and the second FET comprises a second GAA FET.

10. The electronic device of claim 1, wherein the first FET comprises a first FinFET, and the second FET comprises a second FinFET.

11. The electronic device of claim 1, wherein:
the first terminal comprises a first source of the first FET;
the fourth terminal comprises a second drain of the second FET;
the second terminal comprises a first drain of the first FET; and
the third terminal comprises a second source of the second FET coupled to the first drain of the first FET.

12. The electronic device of claim 1, further comprising:
a third FET comprising a third gate, a fifth terminal, and a sixth terminal,
the third FET having a third breakdown voltage between the third gate and the fifth terminal; and
a third varactor circuit comprising a third anode and a third cathode, the third cathode coupled to the third gate;
wherein:
the input node further comprises the third anode coupled to the first anode and the second anode; and
the output node is further coupled to one of the second terminal coupled to the fifth terminal, and the third terminal coupled to the sixth terminal;
the electronic device having the overall breakdown voltage between the first terminal and the fourth terminal greater than the first breakdown voltage, the second breakdown voltage, and the third breakdown voltage.

13. The electronic device of claim 12, wherein:
the first terminal comprises a first source of the first FET;
the second terminal comprises a first drain of the first FET;
the third terminal comprises a second source of the second FET;
the fourth terminal comprises a second drain of the second FET;
the fifth terminal comprises a third source of the third FET;
the sixth terminal comprises a third drain of the third FET;
the first drain of the first FET is coupled to the third source of the third FET; and
the second source of the second FET is coupled to the third drain of the third FET.

14. The electronic device of claim 1, wherein:
the first varactor circuit comprises:
a first varactor comprising a third anode and the first cathode; and
a third varactor comprising the first anode and a third cathode;
the second varactor circuit comprises:
a second varactor comprising a fourth anode and the second cathode; and
a fourth varactor comprising the second anode and a fourth cathode; and
the electronic device further comprises a second input node comprising the third cathode coupled to the third anode, and the fourth cathode coupled to the fourth anode.

15. The electronic device of claim 14, wherein:
the first FET further comprises a first channel and a first insulator between the first gate and the first channel, the first insulator having a first thickness in a first direction from the first gate to the first channel equal to or less than two (2) nanometers (nm); and
the second FET further comprises a second channel and a second insulator between the second gate and the second channel, the second insulator having a second thickness in a second direction from the second gate to the second channel equal to or less than two (2) nm.

16. The electronic device of claim 15, wherein:
the first varactor comprises a third gate between the third anode and the first cathode, and a third insulator between the third gate and the first cathode, the third insulator having a third thickness equal to the first thickness in a third direction from the third gate to the first cathode;
the second varactor comprises a fourth gate between the fourth anode and the second cathode, and a fourth insulator between the fourth gate and the second cathode, the fourth insulator having a fourth thickness equal to the first thickness in a fourth direction from the fourth gate to the second cathode equal;
the third varactor comprises a fifth gate between the first anode and the third cathode, and a fifth insulator between the fifth gate and the third cathode, the fifth insulator having a fifth thickness equal to the first thickness in a fifth direction from the fifth gate to the third cathode; and
the fourth varactor comprises a sixth gate between the second anode and the fourth cathode, and a sixth insulator between the sixth gate and the fourth cathode, the sixth insulator having a sixth thickness equal to the first thickness in a sixth direction from the sixth gate to the fourth cathode.

17. The electronic device of claim 16, wherein:
the first varactor comprises a third gate between the third anode and the first cathode, and a third insulator between the third gate and the first cathode, the third insulator having a third thickness equal to the first thickness in a third direction from the third gate to the first cathode;
the second varactor comprises a fourth gate between the fourth anode and the second cathode, and a fourth insulator between the fourth gate and the second cathode, the fourth insulator having a fourth thickness equal to the first thickness in a fourth direction from the fourth gate to the second cathode;
the third varactor comprises a fifth gate between the first anode and the third cathode, and a fifth insulator between the fifth gate and the third cathode, the fifth insulator having a fifth thickness equal to the first thickness in a fifth direction from the fifth gate to the third cathode; and
the fourth varactor comprises a sixth gate between the second anode and the fourth cathode, and a sixth insulator between the sixth gate and the fourth cathode, the sixth insulator having a sixth thickness equal to the first thickness in a sixth direction from the sixth gate to the fourth cathode.

18. The electronic device of claim 1 integrated into a device selected from the group consisting of: a set top box; an entertainment unit; a navigation device; a communications device; a fixed location data unit; a mobile location data unit; a global positioning system (GPS) device; a mobile phone; a cellular phone; a smart phone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; an avionics system; a drone; and a multicopter.

19. An electronic device comprising:
a first circuit, comprising:
a first diffusion region in a substrate having a first polarity;
a first varactor circuit comprising a first anode and a first cathode formed in the first diffusion region;
a second varactor circuit comprising a second anode and a second cathode formed in the first diffusion region;
a second diffusion region in the substrate having a second polarity opposite from the first polarity;
a first field-effect transistor (FET) comprising a first gate, a first terminal, and a second terminal in the second diffusion region;
a second FET comprising a second gate, a third terminal, and a fourth terminal in the second diffusion region, the third terminal coupled in series to the second terminal;
a first gate structure extending in the first diffusion region and the second diffusion region and comprising the first gate of the first FET in the second diffusion region, the first gate structure coupled to the first cathode to couple the first cathode to the first gate; and
a second gate structure extending in the first diffusion region and the second diffusion region and comprising the second gate of the second FET in the second diffusion region, the second gate structure coupled to the second cathode to couple the second cathode to the second gate; and
an input node coupled to the first anode and the second anode; and
an output node coupled to at least one of the second terminal and the third terminal.

20. The electronic device of claim 19, wherein:
the first FET has a first breakdown voltage between the first gate and the first terminal;
the second FET has a second breakdown voltage between the second gate and the fourth terminal; and
the electronic device has an overall breakdown voltage between the first terminal and the fourth terminal greater than the first breakdown voltage and the second breakdown voltage.

21. The electronic device of claim 19, further comprising:
a first contact coupled to the first anode; and
a second contact coupled to the second anode;
wherein:
the input node comprises a first metal line in a first metal layer coupled to the first contact coupled to the first anode and the second contact coupled to the second anode.

22. The electronic device of claim 19, wherein:
the first circuit further comprises a P-type semiconductor (P)-well;
the first diffusion region comprises a P implant in the P-well;
the second diffusion region comprises an N-type semiconductor (N) implant in the P-well;
the first FET comprises a first NFET, wherein:
the first terminal comprises a first N terminal; and
the second terminal comprises a second N terminal; and
the second FET comprises a second NFET, wherein:
the third terminal comprises a third N terminal; and
the fourth terminal comprises a fourth N terminal.

23. The electronic device of claim 19, wherein:
the first circuit further comprises an N-type semiconductor (N)-well;
the first diffusion region comprises an N implant in the N-well;
the second diffusion region comprises a P-type semiconductor (P) implant in the N-well;
the first FET comprises a first PFET, wherein:
the first terminal comprises a first P terminal; and
the second terminal comprises a second P terminal; and
the second FET comprises a second PFET, wherein:
the third terminal comprises a third P terminal; and
the fourth terminal comprises a fourth P terminal.

24. The electronic device of claim 19, wherein the first circuit further comprises:
a third varactor circuit comprising a third anode and a third cathode in the first diffusion region;
a third FET comprising a third gate, a fifth terminal, and a sixth terminal in the second diffusion region; and
a third gate structure extending in the first diffusion region and the second diffusion region and comprising the third gate in the second diffusion region, the third gate structure coupled to the third cathode to couple the third cathode to the third gate;
wherein:
the input node further comprises the third anode coupled to the first anode and the second anode; and
the output node is further coupled to one of the second terminal coupled to the fifth terminal, and the third terminal coupled to the sixth terminal.

25. The electronic device of claim 24, further comprising:
a first contact coupled to the first anode;
a second contact coupled to the second anode; and
a third contact coupled to the third anode;
wherein:
the input node comprises a first metal line in a first metal layer coupled to the first contact coupled to the first anode, coupled to the second contact coupled to the second anode; and coupled to the third contact coupled to the third anode.

26. The electronic device of claim 24, wherein:
the first circuit further comprises a P-type semiconductor (P)-well;
the first diffusion region comprises a P implant in the P-well;
the second diffusion region comprises an N-type semiconductor (N) implant in the P-well;
the first FET comprises a first NFET, wherein:
the first terminal comprises a first N terminal; and
the second terminal comprises a second N terminal;
the second FET comprises a second NFET, wherein:
the third terminal comprises a third N terminal; and
the fourth terminal comprises a fourth N terminal; and
the third FET comprises a third NFET, wherein:
the fifth terminal comprises a fifth N terminal; and
the sixth terminal comprises a sixth N terminal.

27. The electronic device of claim 24, wherein:
the first circuit further comprises an N-type semiconductor (N)-well;
the first diffusion region comprises an N implant in the N-well;
the second diffusion region comprises a P-type semiconductor (P) implant in the N-well;
the first FET comprises a first PFET, wherein:
the first terminal comprises a first P terminal; and
the second terminal comprises a second P terminal;
the second FET comprises a second PFET, wherein:
the third terminal comprises a third P terminal; and
the fourth terminal comprises a fourth P terminal; and
the third FET comprises a third PFET, wherein:
the fifth terminal comprises a fifth P terminal; and
the sixth terminal comprises a sixth P terminal.

28. The electronic device of claim 24, wherein:
the first terminal comprises a first source of the first FET;
the second terminal comprises a first drain of the first FET;
the third terminal comprises a second source of the second FET;
the fourth terminal comprises a second drain of the second FET;
the fifth terminal comprises a third source of the third FET;
the sixth terminal comprises a third drain of the third FET;
the first drain of the first FET is coupled to the third source of the third FET; and
the second source of the second FET is coupled to the third drain of the third FET.

29. The electronic device of claim 19, wherein:
the first varactor circuit comprises:
a first varactor comprising a third anode and the first cathode formed in the first diffusion region; and
a third varactor comprising the first anode and a third cathode;
the second varactor circuit comprises:
a second varactor comprising a fourth anode and the second cathode formed in the first diffusion region; and
a fourth varactor comprising the second anode and a fourth cathode; and
further comprising:
a first contact coupled to the third anode; and
a second contact coupled to the fourth anode;
a second circuit, comprising:
a third diffusion region having the second polarity,
the third varactor and the fourth varactor formed in the third diffusion region;
a third contact coupled to the third cathode; and
a fourth contact coupled to the fourth cathode;
wherein:
the input node comprises a first metal line in a first metal layer coupled to first contact, the second contact, the third contact, and the fourth contact; and
the second circuit further comprises:
a third gate structure in the third diffusion region, the third gate structure coupled to the first anode; and
a fourth gate structure in the third diffusion region, the fourth gate structure coupled to the second anode; and
further comprising:
a second input node comprising a second metal line in a second metal layer coupled to the third gate structure and the fourth gate structure to couple the second input node to the first anode and the second anode.

30. The electronic device of claim 29, wherein the first metal layer comprises the second metal layer.

31. The electronic device of claim 29, wherein:
the first circuit further comprises a P-type semiconductor (P)-well;
the first diffusion region comprises a P implant in the P-well;
the second diffusion region comprises an N-type semiconductor (N) implant in the P-well;
the first FET comprises a first NFET, wherein:
the first terminal comprises a first N terminal; and
the second terminal comprises a second N terminal; and
the second FET comprises a second NFET, wherein:
the third terminal comprises a third N terminal; and
the fourth terminal comprises a fourth N terminal;
the second circuit further comprises an N well (N-well); and
the third diffusion region comprises an N implant in the N-well.

32. The electronic device of claim 29, wherein:
the first circuit further comprises an N-type semiconductor (N)-well;
the first diffusion region comprises a N implant in the N-well;
the second diffusion region comprises P-type semiconductor (P) implant in the N-well;
the first FET comprises a first PFET, wherein:
the first terminal comprises a first P terminal; and
the second terminal comprises a second P terminal; and
the second FET comprises a second PFET, wherein:
the third terminal comprises a third P terminal; and
the fourth terminal comprises a fourth P terminal;
the second circuit further comprises a P well (P-well); and
the third diffusion region comprises a P implant in the P-well.

33. The electronic device of claim 19 integrated into a device selected from the group consisting of: a set top box; an entertainment unit; a navigation device; a communications device; a fixed location data unit; a mobile location data unit; a global positioning system (GPS) device; a mobile phone; a cellular phone; a smart phone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; an avionics system; a drone; and a multicopter.

34. A method of fabricating an electronic device, comprising:
forming a first diffusion region in a substrate having a first polarity;
forming a first varactor circuit comprising a first anode and a first cathode, and a second varactor circuit comprising a second anode and a second cathode in the first diffusion region;
forming a second diffusion region in the substrate having a second polarity opposite from the first polarity;
forming a first field-effect transistor (FET) comprising a first gate, a first terminal, and a second terminal, and a second FET comprising a second gate, a third terminal, and a fourth terminal in the second diffusion region, the third terminal coupled in series to the second terminal;
forming a first gate structure extending in the first diffusion region and the second diffusion region and comprising the first gate of the first FET in the second diffusion region, the first gate structure coupled to the first cathode to couple the first cathode to the first gate; and
forming a second gate structure extending in the first diffusion region and the second diffusion region and comprising the second gate of the second FET in the second diffusion region, the second gate structure coupled to the second cathode to couple the second cathode to the second gate.

35. The method of claim 34, further comprising:
forming a third varactor circuit comprising a third anode and a third cathode in the first diffusion region;
forming a third FET comprising a third gate, a fifth terminal, and a sixth terminal in the second diffusion region; and
forming a third gate structure extending in the first diffusion region and the second diffusion region and comprising the third gate in the second diffusion region, the third gate structure coupled to the third cathode to couple the third cathode to the third gate.

36. The method of claim 34, further comprising:
forming a third diffusion region in the substrate having the second polarity;
wherein:
forming the first varactor circuit comprises:
forming a first varactor comprising a third anode and the first cathode formed in the first diffusion region; and
forming a third varactor comprising the first anode and a third cathode formed in the third diffusion region;
forming the second varactor circuit comprises:
forming a second varactor comprising a fourth anode and the second cathode formed in the first diffusion region; and
forming a fourth varactor comprising the second anode and a fourth cathode formed in the third diffusion region; and
further comprising:
forming a first contact coupled to the third anode; and
forming a second contact coupled to the fourth anode;
forming a third contact coupled to the third cathode; and
forming a fourth contact coupled to the fourth cathode;
forming a third gate structure in the third diffusion region, the third gate structure coupled to the first anode; and
forming a fourth gate structure in the third diffusion region, the fourth gate structure coupled to the second anode.
